(19) United States
(12) Patent Application Publication
(10) Pub. No.: US 2026/0314043 A1
(43) Pub. Date: Oct. 8, 2026

(54) SEMICONDUCTOR DEVICES

(71) Applicant: SAMSUNG ELECTRONICS CO., LTD., Suwon-si (KR)

(72) Inventors: Daihong HUH, Suwon-si (KR); Dahye KIM, Suwon-si (KR); Cheoljin YUN, Suwon-si (KR); Sungyub JI, Suwon-si (KR)

(73) Assignee: SAMSUNG ELECTRONICS CO., LTD., Suwon-si (KR)

(21) Appl. No.: 19/635,194

(22) Filed: Mar. 31, 2026

(30) Foreign Application Priority Data
Apr. 2, 2025 (KR) 10-2025-0042705

(51) Int. Cl. H10D 84/83; H10B 80/00; H10D 30/00; H10D 30/01; H10D 30/43; H10D 62/10; H10D 62/13; H10D 64/23; H10D 80/30; H10D 84/01; H10W 90/00

(52) U.S. Cl. CPC H10D 84/83125; H10D 30/43; H10D 30/502; H10D 62/121; H10D 62/151; H10D 64/254; H10D 64/256; H10D 84/8312; H10D 84/832; H10B 80/00; H10D 30/014; H10D 30/0191; H10D 80/30; H10D 84/0133; H10D 84/0149; H10W 90/792

(57) ABSTRACT

A semiconductor device includes first and second transistors and a first contact plug. The first transistor includes a first gate structure, first channels and a first source/drain layer. The second transistor is disposed on the first transistor, and includes a second gate structure, second channels and a second source/drain layer. The first contact plug extends through the second source/drain layer and contacts an upper surface of the first source/drain layer. A first width in the second direction of a central portion in the first direction of the first contact plug is smaller than a second with in the second direction of each of opposite end portions in the first direction of the first contact plug.

### CROSS-REFERENCE TO RELATED APPLICATION

This application claims priority under 35 USC § 119 to Korean Patent Application No. 10-2025-0042705, filed on Apr. 2, 2025 in the Korean Intellectual Property Office (KIPO), the contents of which are herein incorporated by reference in their entirety.

### BACKGROUND

### 1. Field

Example embodiments relate to semiconductor devices.

### 2. Description of the Related Art

In order to highly integrate a semiconductor device, a method of stacking a plurality of transistors in a vertical direction has been studied. In order to transfer electrical signals to a lower transistor, a contact plug connected to an upper wiring is needed to contact a source/drain layer the lower transistor, however, processes for forming the contact plug are not easy.

### SUMMARY

Example embodiments provide a semiconductor device having enhanced characteristics.

According to example embodiments, there is provided a semiconductor device. The semiconductor device may include a first transistor, a second transistor, and a first contact plug. The first transistor may include a first gate structure, first channels and a first source/drain layer. The first gate structure may extend in a first direction. Each of the first channels may extend through the first gate structure in a second direction crossing the first direction, and the first channels may be spaced apart from each other in a third direction perpendicular to the first and second directions. The first source/drain layer may be disposed at a first side in the second direction of the first gate structure. The second transistor may be disposed on the first transistor, and may include a second gate structure, second channels and a second source/drain layer. The second gate structure may extend in the first direction. Each of the second channels may extend through the second gate structure in the second direction, and the second channels may be spaced apart from each other in the third direction. The second source/drain layer may be disposed at a first side in the second direction of the second gate structure. The first contact plug may extend through the second source/drain layer and contact an upper surface of the first source/drain layer. A first width in the second direction of a central portion in the first direction of the first contact plug may be smaller than a second with in the second direction of each of opposite end portions in the first direction of the first contact plug.

According to example embodiments, there is provided a semiconductor device. The semiconductor device may include a first gate structure, first channels, first and second source/drain layers, an insulation pattern structure, a second gate structure, second channels, third and fourth source/drain layers, a first contact plug and a second contact plug. Each of the first channels may extend through the first gate structure in a first direction, and the first channels may be spaced apart from each other in a second direction perpendicular to the first direction. The first and second source/drain layers may be disposed at opposite sides, respectively, in the first direction of the first gate structure. The insulation pattern structure may be disposed on each of the first and second source/drain layers. The second gate structure may be disposed on the first gate structure. Each of the second channels may extend through the second gate structure in the first direction, and the second channels may be spaced apart from each other in the second direction. The third and fourth source/drain layers may be disposed at opposite sides, respectively, in the first direction of the second gate structure. The first contact plug may extend through the third source/drain layer and contact an upper surface of the first source/drain layer. The second contact plug may extend through the fourth source/drain layer and contact an upper surface of the insulation pattern structure. The third source/drain layer and the fourth source/drain layer may have the same shape.

According to example embodiments, there is provided a semiconductor device. The semiconductor device may include a first transistor, an insulation pattern structure, a second transistor, a first contact plug and a second contact plug. The first transistor may include a first gate structure, first channels and first and second source/drain layers. The first gate structure may extend in a first direction. Each of the first channels may extend through the first gate structure in a second direction crossing the first direction, and the first channels may be spaced apart from each other in a third direction perpendicular to the first and second directions. The first and second source/drain layers may be disposed at opposite sides, respectively, in the second direction of the first gate structure. The insulation pattern structure may be disposed on each of the first and second source/drain layers. The second transistor may be disposed on the first transistor, and may include a second gate structure, second channels and third and fourth source/drain layers. The second gate structure may extend in the first direction. Each of the second channels may extend through the second gate structure in the second direction, and the second channels may be spaced apart from each other in the third direction. The third and fourth source/drain layers may be disposed at opposite sides, respectively, in the second direction of the second gate structure on the insulation pattern structure. The first contact plug may extend through the third source/drain layer and contact an upper surface of the first source/drain layer. The second contact plug may extend through the fourth source/drain layer and contact an upper surface of the insulation pattern structure.

In the method of manufacturing the semiconductor device in accordance with example embodiments, openings for forming the contact plugs may be formed by a dry etching process without an etching mask through selectively removing a sacrificial epitaxial pattern having a high etching selectivity with respect to the source/drain layers, and thus etching defects caused by collapse of the etching mask and characteristic degradation of the source/drain layers due to the etching process may be prevented.

Additionally, the source/drain layers may be formed by the same process so as to simplify the manufacturing processes. Furthermore, the source/drain layers may have the same shape so as to have the same electrical performance.

### BRIEF DESCRIPTION OF THE DRAWINGS

FIGS. 1, 2, 3, 4, and 5 are plan views and cross-sectional views illustrating a first semiconductor device in accordance with example embodiments.

FIGS. 6, 7, 8, 9, 10, 11, 12, 13, 14, 15, 16, 17, 18, 19, 20, 21, 22, 23, 24, 25, 26, 27, 28, 29, 30, 31, and 32 are plan views and cross-sectional views illustrating a method of manufacturing a first semiconductor device in accordance with example embodiments.

FIG. 33 is a cross-sectional view illustrating a second semiconductor device in accordance with example embodiments.

FIG. 34 is a cross-sectional view illustrating a third semiconductor device in accordance with example embodiments.

FIG. 35 is a cross-sectional view illustrating a fourth semiconductor device in accordance with example embodiments.

### DESCRIPTION OF EMBODIMENTS

Hereinafter, a semiconductor device and a method for manufacturing the same in accordance with example embodiments will be described in detail with reference to the accompanying drawings. It will be understood that, although the terms “first,” “second,” and/or “third” may be used herein to describe various elements, these elements should not be limited by these terms. These terms are only used to distinguish one element from another element.

In the specifications (and not necessarily in the claims), two directions among horizontal directions that are substantially parallel to an upper surface of a substrate, which may intersect each other, may be referred to as first and second directions D1 and D2, respectively, and a vertical direction that is substantially perpendicular to the upper surface of the substrate may be referred to as a third direction D3. In example embodiments, the first and second directions D1 and D2 may be substantially perpendicular to each other. Each of the first to third directions D1, D2 and D3 may include a direction shown in the drawings and a direction inverse thereto.

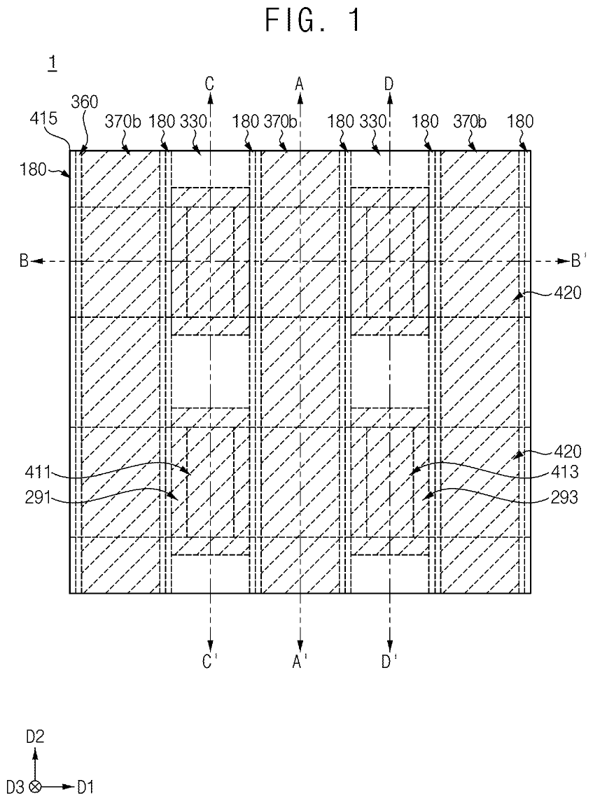

FIGS. 1, 2, 3, 4, and 5 are plan views and cross-sectional views illustrating a first semiconductor device 1 in accordance with example embodiments.

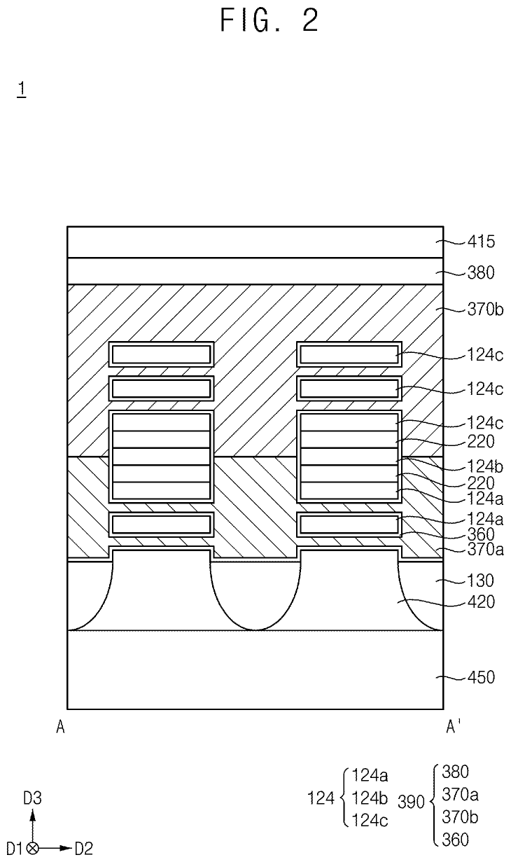

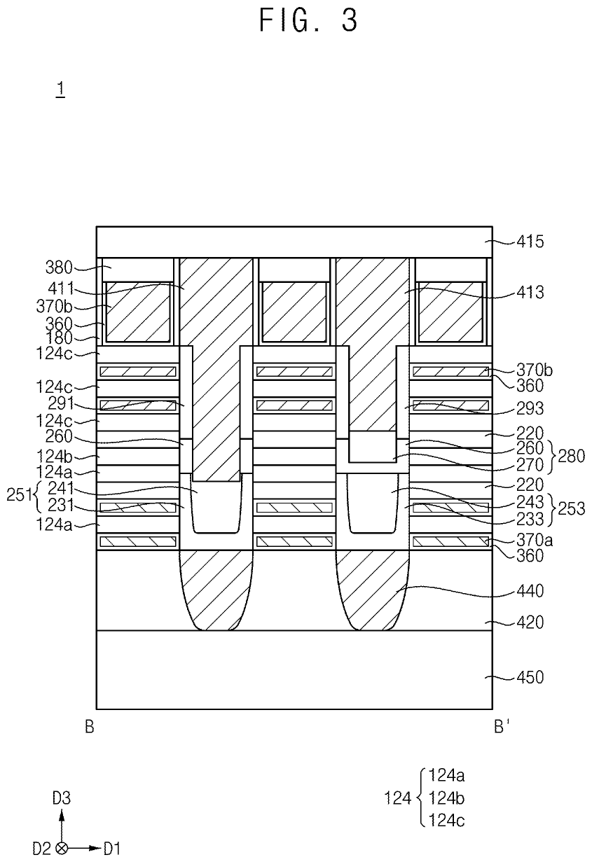

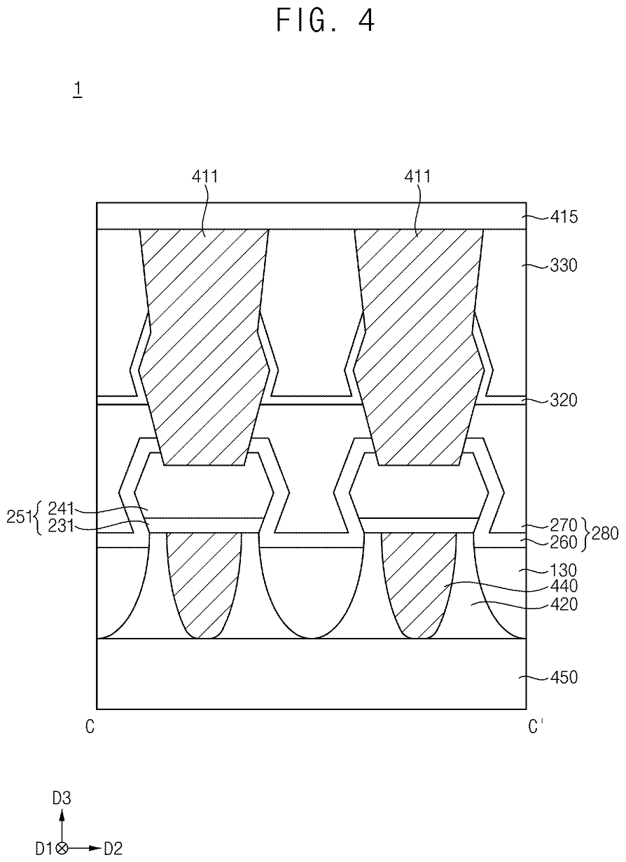

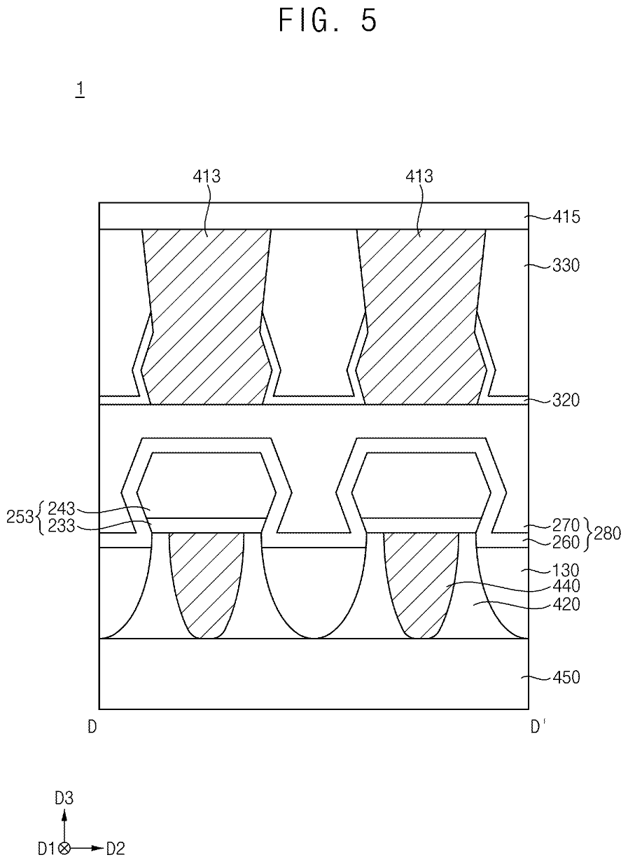

Particularly, FIG. 1 is the plan view, and FIGS. 2, 3, 4, 5, and 6 are the cross-sectional views. FIG. 2 is a cross-sectional view taken along line A-A′ of FIG. 1, FIG. 3 is a cross-sectional view taken along line B-B′ of FIG. 1, FIG. 4 is a cross-sectional view taken along line C-C′ of FIG. 1, and FIG. 5 is a cross-sectional view taken along line D-D′ of FIG. 1.

Referring to FIGS. 1, 2, 3, 4, and 5, the first semiconductor device 1 may include a first gate structure 390, semiconductor patterns 124, a division pattern 220, first, second, third, and fourth source/drain layers 251, 291, 253 and 293, an insulation pattern structure 280, and first, second, and third contact plugs 411, 413 and 440.

The first semiconductor device 1 may further include an isolation pattern 130, a gate spacer 180, first, second and fourth insulating interlayers 330, 415 and 450, a third insulating interlayer pattern 420, an upper via (not shown), an upper wiring (not shown), a lower via (not shown) and a lower wiring (not shown).

The fourth insulating interlayer 450 and the third insulating interlayer pattern 420 may be sequentially stacked in the third direction D3 upwardly. In example embodiments, the third insulating interlayer pattern 420 may extend in the first direction D1 on the fourth insulating interlayer 450, and a plurality of third insulating interlayer patterns 420 may be spaced apart from each other in the second direction D2.

The fourth insulating interlayer 450 may include the lower wiring and the lower via, and the lower wiring may extend through the fourth insulating interlayer 450. In an example embodiment, a plurality of lower vias may be spaced apart from each other in each of the first and second directions D1 and D2, and the lower wiring may extend in the first direction D1 or the second direction D2 and may commonly contact the lower vias. The lower wiring may serve as a power rail of the first semiconductor device 1.

In example embodiments, each of the third insulating interlayer pattern 420 and the fourth insulating interlayer 450 may include an insulating interlayer material, e.g., silicon oxycarbide, silicon oxide, silicon nitride, silicon oxynitride, silicon carbonitride, silicon oxycarbonitride, etc.

The third contact plug 440 may extend through the third insulating interlayer pattern 420 and may contact the lower via. The third contact plug 440 may have a shape in which a width thereof in the first direction D1 and/or the in the second direction D2 decreases downwardly in the third direction D3, e.g., a trapezoidal shape. In example embodiments, a plurality of third contact plugs 440 may be spaced apart from each other in each of the first and second directions D1 and D2.

Each of the lower wiring, the lower via and the third contact plug 440 may include a conductive material, e.g., a metal, a metal nitride, a metal silicide, etc.

The isolation pattern 130 may be disposed on the fourth insulating interlayer 450 and may cover a sidewall of the third insulating interlayer pattern 420. In example embodiments, the isolation pattern 130 may extend in the first direction D1 between neighboring ones of the third insulating interlayer patterns 420 in the second direction D2, and a plurality of isolation patterns 130 may be spaced apart from each other in the second direction D2.

### Each of the Third Insulating Interlayer Pattern 420 and the Isolation Pattern 130 May include an oxide, e.g., silicon oxide.

The semiconductor patterns 124 may be disposed at a plurality of levels, respectively, spaced apart from each other in the third direction D3 on an upper surface of third insulating interlayer pattern 420, and each of the semiconductor patterns 124 may extend in the first direction D1 to a given length. Hereinafter, first ones of the semiconductor patterns 124 at lower levels may be referred to as first semiconductor patterns 124a, respectively, second ones of the semiconductor patterns 124 at middle levels may be referred to as second semiconductor patterns 124b, respectively, and third ones of the semiconductor patterns 124 at higher levels may be referred to as third semiconductor patterns 124c, respectively.

The division pattern 220 may be disposed between an uppermost one of the first semiconductor patterns 124a and a lowermost one of the third semiconductor patterns 124c. In example embodiments, a plurality of division patterns 220 may be disposed at a plurality of levels spaced apart from each other in the third direction D3, and each of the division patterns 220 may extend in the first direction D1 to a given length. The second semiconductor pattern 124b may be disposed between neighboring ones of the division patterns 220 in the third direction D3.

Alternatively, in some embodiments, the division pattern 220 may be disposed at a single level, and a thickness in the third direction D3 of the division pattern 220 may be greater than a thickness in the third direction D3 of each of the semiconductor patterns 124.

FIGS. 2 and 3 show that the semiconductor patterns 124 are disposed at six levels, respectively, and include one first semiconductor pattern 124a, two second semiconductor patterns 124b and three third semiconductor patterns 124c. However, the present disclosure is not limited thereto. If the division pattern 220 is disposed at a single level, the semiconductor patterns 124 may not include the second semiconductor pattern 124b.

FIG. 3 shows that three semiconductor patterns 124 are spaced apart from each other in the first direction D1 on the third insulating interlayer pattern 420 at the same level. However, the present disclosure is not limited thereto, and a plurality of semiconductor patterns 124 may be spaced apart from each other in the first direction D1 on the third insulating interlayer pattern 420 at the same level.

In example embodiments, the semiconductor patterns 124 may include a nanosheet or a nano-wire including, e.g., silicon. In example embodiments, each of the first and third semiconductor patterns 124a and 124c may serve as a channel in a transistor and thus may also be referred to as a channel. The second semiconductor pattern 124b may not serve as a channel and thus may also referred to as a dummy channel.

The first gate structure 390 may extend in the second direction D2 on the third insulating interlayer pattern 420 and the isolation pattern 130, and a plurality of first gate structures 390 may be spaced apart from each other in the first direction D1. The first gate structure 390 may include a first gate insulation pattern 360, first and second gate electrodes 370a and 370b and a second capping pattern 380. In example embodiments, the first gate structure 390 may cover lower and upper surfaces and opposite sidewalls in the second direction D2 of a central portion in the first direction D1 of each of the semiconductor patterns 124.

The first gate insulation pattern 360 may be disposed on a surface of each of the first and third semiconductor patterns 124a and 124c, sidewalls of the second semiconductor pattern 124b and the division pattern 220, upper surfaces of the third insulating interlayer pattern 420 and the isolation pattern 130, a sidewall of each of the first, second, third, and fourth source/drain layers 251, 291, 253 and 293, and an inner sidewall of the gate spacer 180.

The first gate electrode 370a may be disposed on a portion of the first gate insulation pattern 360 covering the third insulating interlayer pattern 420 and the isolation pattern 130 and may fill a space between neighboring ones of the first semiconductor patterns 124a in the third direction D3 and between a lowermost one of the first semiconductor patterns 124a and the third insulating interlayer pattern 420.

The second gate electrode 370b may be disposed on the first gate electrode 370a and may fill a space between neighboring ones of the third semiconductor patterns 124c in the third direction D3 and between neighboring ones of the gate spacers 180 on an uppermost one of the third semiconductor patterns 124c.

In example embodiments, an upper surface of the first gate electrode 370a may be higher than the uppermost one of the first semiconductor patterns 124a and may be lower a lower surface of a lowermost one of the third semiconductor patterns 124c. That is, the upper surface of the first gate electrode 370a may be higher than a lower surface of a lowermost one of the division patterns 220 and may be lower than an upper surface of an uppermost one of the division patterns 220. Additionally, a lower surface of the second gate electrode 370b may be higher than the upper surface of the uppermost one of the first semiconductor patterns 124a and may be lower than the lower surface of the lowermost one of the third semiconductor patterns 124c.

In an example embodiment, a third insulating interlayer pattern may be disposed between the first gate electrode 370a and the second gate electrode 370b, and may insulate the first gate electrode 370a from the second gate electrode 370b. The third insulation pattern may include, e.g., silicon nitride, silicon oxide, etc. Alternatively, the first and second gate electrodes 370a and 370b may contact each other and may be integrally formed.

The second capping pattern 380 may contact upper surfaces of the first gate insulation pattern 360 and the second gate electrode 370b and may also contact the inner sidewall of the gate spacer 180.

Hereinafter, a first portion of the first gate structure 390 at a height higher than the upper surface of the third semiconductor patterns 124c may be referred to as an upper portion, and a second portion of the first gate structure 390 beneath the first portion thereof may be referred to as a lower portion.

The first gate insulation pattern 360 may include an oxide, e.g., silicon oxide.

Each of the first and second gate electrodes 370a and 370b may include a metal nitride, a metal alloy, a metal carbide, a metal oxynitride, a metal carbonitrde, a metal oxycarbonitride, e.g., titanium nitride, titanium aluminum nitride, tantalum nitride, tantalum aluminum nitride, titanium aluminum, titanium aluminum carbide, titanium aluminum oxynitride, titanium aluminum carbonitrde, titanium aluminum oxycarbonitride, etc., or a low-resistance metal, e.g., tungsten, aluminum, copper, tantalum, etc.

In example embodiments, each of the first and second gate electrodes 370a and 370b may have a single-layered structure. Alternatively, each of the first and second gate electrodes 370a and 370b may have a multi-layered structure including different conductive materials from each other.

The second capping pattern 380 may include an insulating nitride, e.g., silicon nitride.

The gate spacer 180 may be disposed on each of opposite sidewalls in the first direction D1 of the upper portion of the first gate structure 390. The gate spacer 180 may include an insulating nitride, e.g., silicon nitride or an oxide, e.g., silicon oxide.

The first and third source/drain layers 251 and 253 may be disposed at opposite sides, respectively, in the first direction D1 of the first gate structure 390 on the third insulating interlayer pattern 420 and the third contact plug 440, and may contact a lower portion of a sidewall in the first direction D1 of the lower portion of the first gate structure 390, sidewalls in the first direction D1 of the first semiconductor patterns 124a, and a portion of a sidewall in the first direction D1 of the division pattern 220.

The first source/drain layer 251 may include a first epitaxial pattern 231 and a second epitaxial pattern 241. The third source/drain layer 253 may include a third epitaxial pattern 233 and a fourth epitaxial pattern 243.

In example embodiments, each of the second and fourth epitaxial patterns 241 and 243 may have a pillar shape extending in the third direction D3, and a sidewall and a lower surface of each of the second and fourth epitaxial patterns 241 and 243 may be covered by the first and second and third epitaxial patterns 231 and 233, respectively.

In example embodiments, each of the first, second, third, and fourth epitaxial patterns 231, 241, 233 and 243 may include silicon-germanium or silicon-germanium doped with p-type impurities, e.g., boron, gallium, etc. A concentration of the p-type impurities in silicon-germanium of each of the first and third epitaxial patterns 231 and 233 may be lower than a concentration of the p-type impurities in silicon-germanium of each of the second and fourth epitaxial patterns 241 and 243.

Each of the first and third source/drain layers 251 and 253 may serve as a source/drain of a PMOS transistor. A vertical cross-section of each of the first and third source/drain layers 251 and 253 may have a shape of, e.g., a pentagon or a hexagon.

The insulation pattern structure 280 may be disposed on the isolation pattern 130, the third insulating interlayer pattern 420, and the first and third source/drain layers 251 and 253 and may include a first insulation pattern 260 and a second insulation pattern 270 sequentially stacked.

The first insulation pattern 260 may conformally cover an upper surface of the division pattern 220, an upper portion of a sidewall of the third insulating interlayer pattern 420, and surfaces of the first and third source/drain layers 251 and 253. The second insulation pattern 270 may be disposed on the first insulation pattern 260 and may fill a space between neighboring ones of the first source/drain layer 251 in the second direction D2 and between neighboring ones of the second source/drain layer 291 in the second direction D2.

A first capping pattern 320 may be disposed on the insulation pattern structure, and may include an insulating material, e.g., silicon nitride, silicon oxide, etc.

The second and fourth source/drain layers 291 and 293 may be disposed at opposite sides, respectively, in the first direction D1 of the first gate structure 390 on the insulation pattern structure 280 and may contact an upper portion of the sidewall in the first direction D1 of the lower portion of the first gate structure 390, sidewalls in the first direction D1 of the third semiconductor patterns 124c, and a portion of the sidewall in the first direction D1 of the division pattern 220.

In example embodiments, each of the second and fourth source/drain layers 291 and 293 may include silicon or silicon doped with n-type impurities, e.g., arsenic, phosphorus, etc. In an example embodiment, each of the second and fourth source/drain layers 291 and 293 may have a multi-layered structure, and a concentration of the n-type impurities in silicon of each of the second and fourth source/drain layers 291 and 293 may gradually decrease toward the first gate structure 390.

Each of the second and fourth source/drain layers 291 and 293 may serve as a source/drain of an NMOS transistor. In example embodiments, the second and fourth source/drain layers 291 and 293 may have substantially the same shape.

The first contact plug 411 may be disposed on the first source/drain layer 251 and may extend in the third direction D3. The first contact plug 411 may include a lower portion, which may extend through the second source/drain layer 291 and the insulation pattern structure 280 to contact an upper surface of the first source/drain layer 251, and an upper portion, which may be disposed on and contact the lower portion and extend through the first insulating interlayer 330 in the third direction D3.

In example embodiments, a sidewall in the second direction D2 of the upper portion of the first contact plug 411 may contact the first insulating interlayer 330, and a sidewall in the first direction D1 of the upper portion of the first contact plug 411 may contact an outer sidewall of the gate spacer 180. A sidewall in the second direction D2 of the lower portion of the first contact plug 411 may contact the first capping pattern 320 and the insulation pattern structure 280.

A central portion in the second direction D2 of the lower portion of the first contact plug 411 may have a first width in the first direction D1 and may contact a sidewall in the first direction D1 of the second source/drain layer 291. Each of opposite sidewalls in the second direction D2 of the lower portion of the first contact plug 411 may have a second width in the first direction D1 that is greater than the first width and may contact a sidewall in the second direction D2 of the second source/drain layer 291. Thus, a cross-section in the horizontal direction of the lower portion of the first contact plug 411, that is, a cross-section in the horizontal direction of a portion of the first contact plug 411 penetrating through the second source/drain layer 291, may have a shape of, e.g., an “H.” A width in the second direction D2 of the lower portion of the first contact plug 411 may gradually increase and then gradually decrease from an upper surface of the lower portion toward a lower surface thereof.

The second contact plug 413 may be disposed on the insulation pattern structure 280 and may extend in the third direction D3. The second contact plug 413 may include a lower portion, which may extend through the fourth source/drain layer 293 to contact an upper surface of the second insulation pattern 270, and an upper portion, which may be disposed on and contact the lower portion and extend through the first insulating interlayer 330 in the third direction D3.

A central portion in the second direction D2 of the lower portion of the second contact plug 413 may have the first width in the first direction D1 and may contact a sidewall in the first direction D1 of the fourth source/drain layer 293. Each of opposite sidewalls in the second direction D2 of the lower portion of the second contact plug 413 may have the second width in the first direction D1 and may contact a sidewall in the second direction D2 of the fourth source/drain layer 293. Thus, a cross-section in the horizontal direction of the lower portion of the second contact plug 413 may have a shape of, e.g., an “H.” A width in the second direction D2 of the lower portion of the second contact plug 413 may gradually increase and then gradually decrease from an upper surface of the lower portion toward a lower surface thereof.

In example embodiments, a sidewall in the second direction D2 of the upper portion of the second contact plug 413 may contact the first insulating interlayer 330, and a sidewall in the first direction D1 of the upper portion of the second contact plug 413 may contact the outer sidewall of the gate spacer 180.

In example embodiments, each of the first and second contact plugs 411 and 413 may include a conductive material, e.g., a metal, a metal nitride, a metal silicide, etc. In an example embodiment, each of the first and second contact plugs 411 and 413 may include a metal pattern, a barrier pattern covering a sidewall and a lower surface of the metal pattern, and an ohmic contact pattern. The ohmic contact pattern may be disposed between the first contact plug 411 and each of the first and second source/drain layers 251 and 291, and between the second contact plug 413 and the fourth source/drain layer 293. The metal pattern may include, e.g., a metal, the barrier pattern may include, e.g., a metal nitride, and the ohmic contact pattern may include, e.g., a metal silicide.

The first and second insulating interlayers 330 and 415 may be sequentially stacked on the insulation pattern structure 280 in the third direction D3.

The first insulating interlayer 330 may be disposed on the first capping pattern 320 and may fill a space between neighboring ones of the first contact plugs 411 in the second direction D2 and a space between neighboring ones of the second contact plugs 413 in the second direction D2. The first insulating interlayer 330 may partially cover the outer sidewall of the gate spacer 180 on a sidewall of the first gate structure 390. The second insulating interlayer 415 may be disposed on the first insulating interlayer 330, the first gate structure 390, the gate spacer 180 and the first and second contact plugs 411 and 413.

In example embodiments, each of the first and second insulating interlayers 330 and 415 may include an insulating material, e.g., silicon oxycarbide, silicon oxide, silicon nitride, silicon oxynitride, silicon carbonitride, silicon oxycarbonitride, etc.

Each of the upper via and the upper wiring may be disposed in the second insulating interlayer 415 and may contact one of the first and second contact plugs 411 and 413 and the second gate electrode 370b. Each of the upper via and the upper wiring may include, e.g., a metal and/or a metal nitride.

In example embodiments, the first and third source/drain layers 251 and 253, the first gate electrode 370a, a portion of the first gate insulation pattern 360 on a surface of the first gate electrode 370a and the first semiconductor pattern 124a may collectively form a first transistor. The first transistor may include a plurality of first semiconductor patterns 124a serving as channels, respectively, spaced apart from each other in the third direction D3, and thus may be a multi-bridge channel field effect transistor (MBCFET).

Additionally, the second and fourth source/drain layers 291 and 293, the second gate electrode 370b, a portion of the first gate insulation pattern 360 on a surface of second gate electrode 370b and the third semiconductor pattern 124c may collectively form a second transistor. The second transistor may include a plurality of third semiconductor patterns 124c serving as channels, respectively, spaced apart from each other in the third direction D3, and thus may be an MBCFET.

In example embodiments, each of the first and third source/drain layers 251 and 253 may include silicon-germanium doped with p-type impurities, and thus the first transistor may be a PMOS transistor. Additionally, each of the second and fourth source/drain layers 291 and 293 may include silicon doped with n-type impurities, and thus the second transistor may be an NMOS transistor.

As illustrated above, the first semiconductor device 1 may include the first contact plug 411 extending through the second source/drain layer 291 to contact the upper surface of the first source/drain layer 251, and the second contact plug 413 extending through the fourth source/drain layer 293 to contact an upper surface of the insulation pattern structure 280.

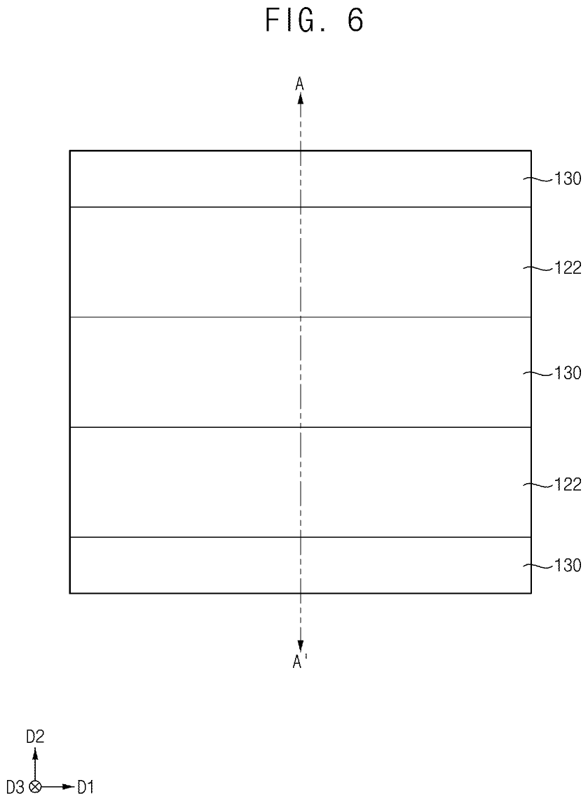

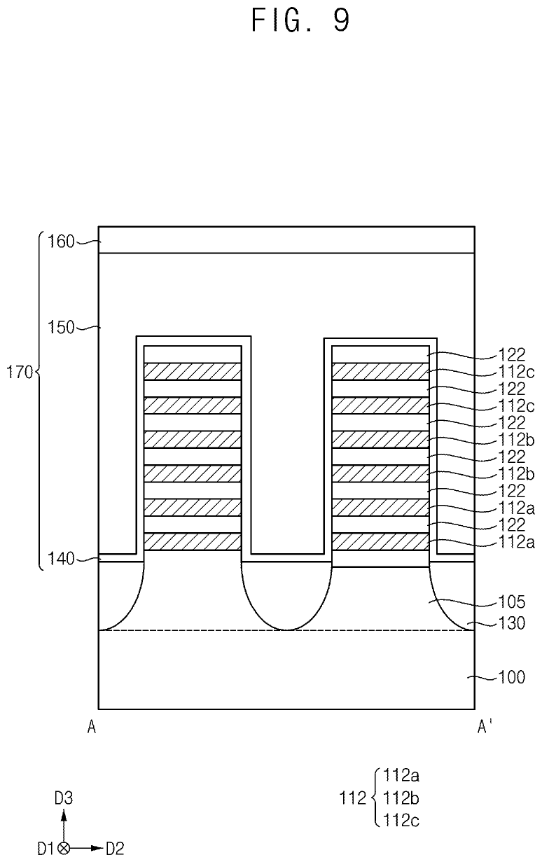

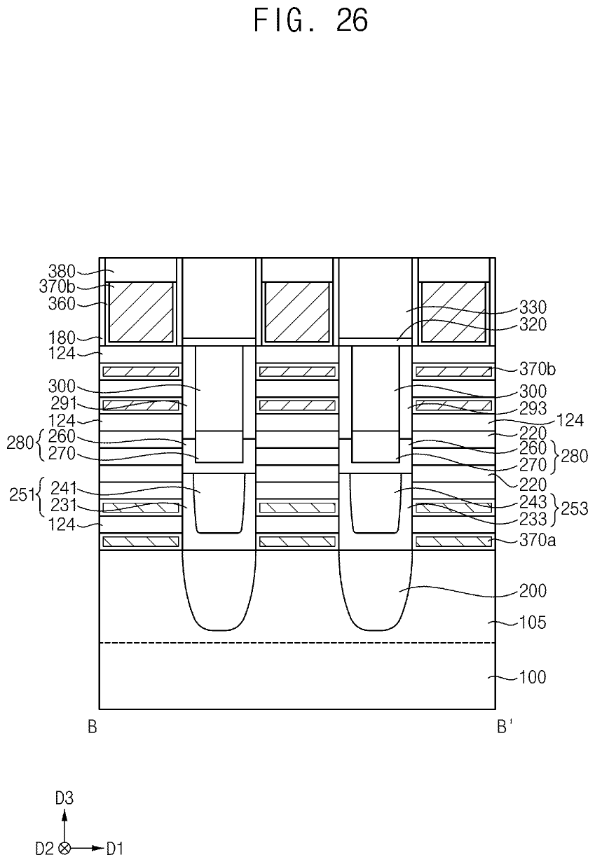

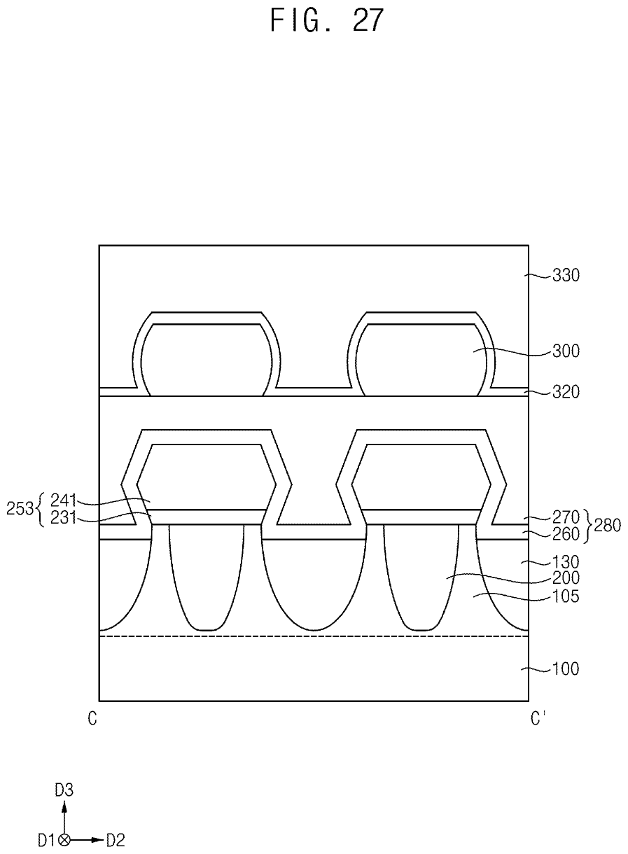

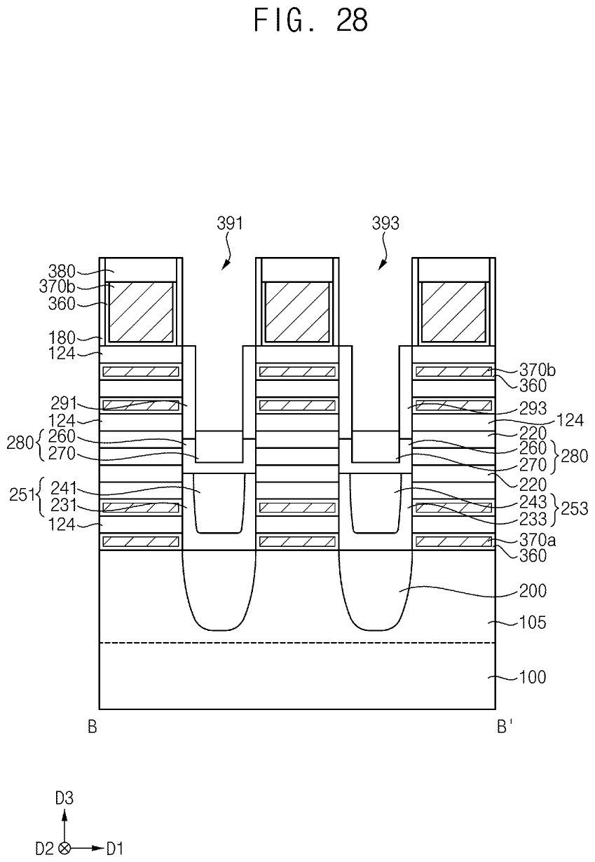

As illustrated below with reference to FIGS. 6, 7, 8, 9, 10, 11, 12, 13, 14, 15, 16, 17, 18, 19, 20, 21, 22, 23, 24, 25, 26, 27, 28, 29, 30, 31, and 32, fifth and sixth openings 391 and 393 (refer to FIG. 28) for forming the first and second contact plugs 411 and 413 may be formed by a dry etching process without an etching mask in which a sacrificial epitaxial pattern 300 (refer to FIG. 26) having a high etching selectivity with respect to the second and fourth source/drain layers 291 and 293 may be selectively removed, and thus etching defects caused by collapse of the etching mask and characteristic degradation of the second and fourth source/drain layers 291 and 293 due to the etching process may be prevented.

The second and fourth source/drain layers 291 and 293 may be formed to have the same shape by the same selective epitaxial growth (SEG) process and thus may have the same performance. Additionally, the first and second contact plugs 411 and 413 may be formed in the fifth and sixth openings 391 and 393, which may be formed by the same process for removing the sacrificial epitaxial patterns 300, and thus may have the same shape at the same level.

FIGS. 6, 7, 8, 9, 10, 11, 12, 13, 14, 15, 16, 17, 18, 19, 20, 21, 22, 23, 24, 25, 26, 27, 28, 29, 30, 31 and 32 are plan views and cross-sectional views illustrating a method of manufacturing the first semiconductor device 1 in accordance with example embodiments.

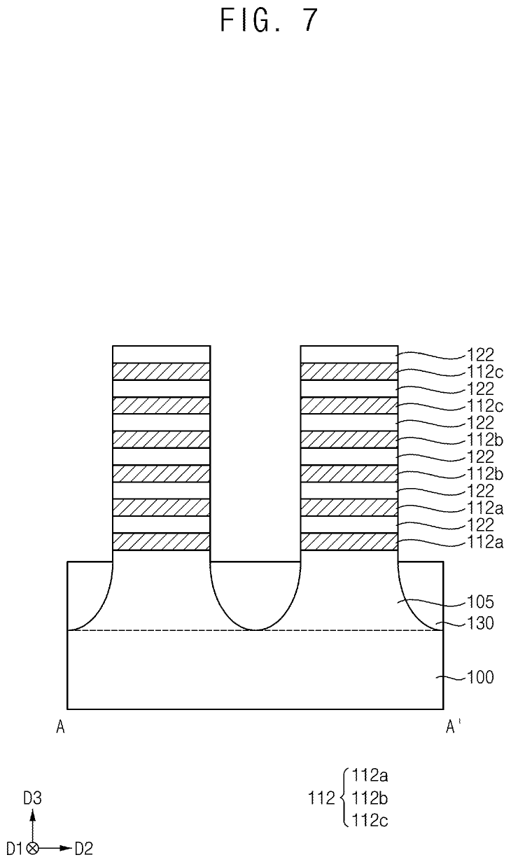

Particularly, FIGS. 6, 8, 11, 18 and 24 are the plan views, and FIGS. 7, 9, 10, 12, 13, 14, 15, 16, 17, 19, 20, 21, 22, 23, 25 , 26, 27, 28, 29, 30, 31, and 32 are the cross-sectional views.

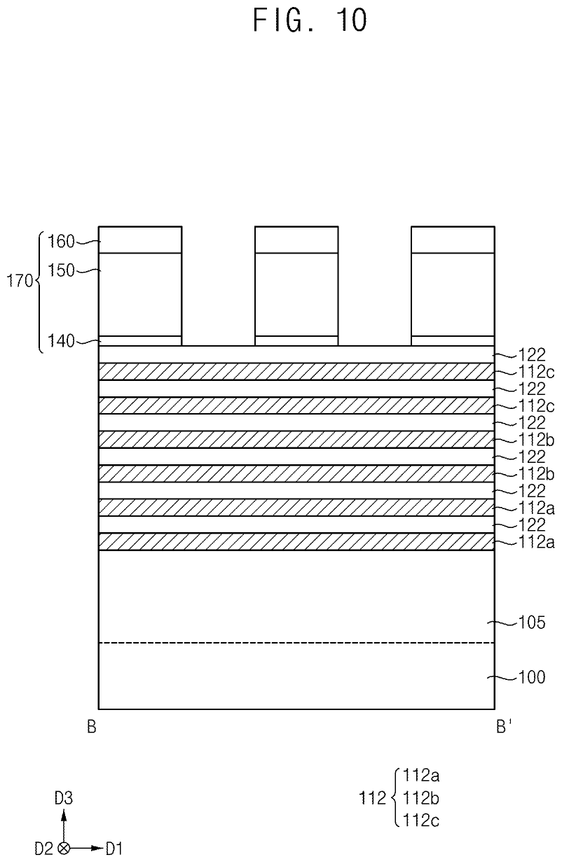

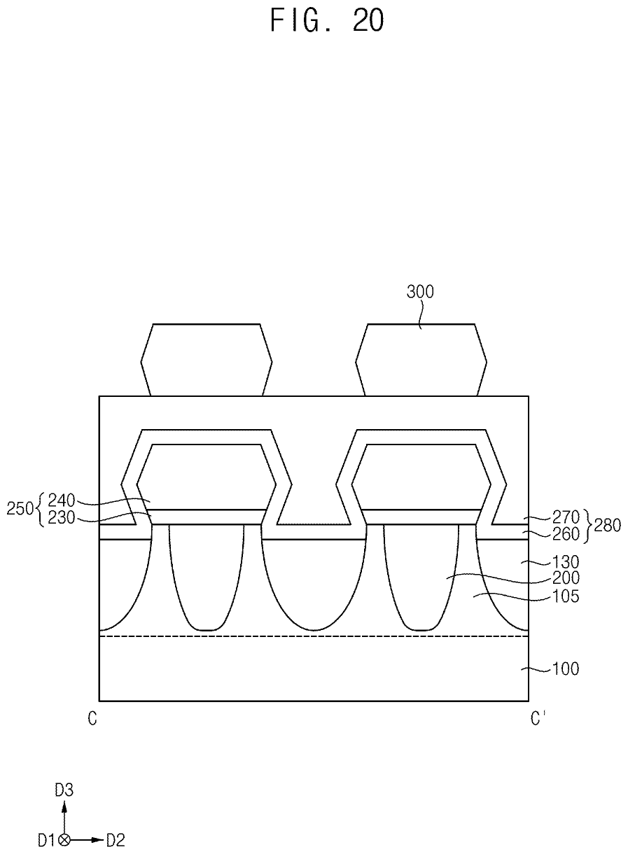

FIGS. 7, 9, 22 and 25 are cross-sectional views taken along lines A-A′ of corresponding plan views, respectively, FIGS. 10, 12, 13, 14, 15, 16, 17, 19, 21, 23, 26, 28, 29, 30, 31, and 32 are cross-sectional views taken along lines B-B′ of corresponding plan views, respectively, and FIGS. 20 and 26 are cross-sectional views taken along lines C-C′ of corresponding plan views, respectively.

Referring to FIGS. 6 and 7, sacrificial layers and semiconductor layers may be alternately and repeatedly stacked on a substrate 100 in the third direction D3, a first etching mask extending in the first direction D1 may be formed on an uppermost one of the semiconductor layers, and the semiconductor layers, the sacrificial layers and an upper portion of the substrate 100 may be etched using the first etching mask.

Thus, an active pattern 105 extending in the first direction D1 may be formed on the substrate 100, and a fin structure including sacrificial lines 112 and semiconductor lines 122 alternately and repeatedly stacked in the third direction D3 may be formed on the active pattern 105. Hereinafter, first ones of the sacrificial lines 112 at lower levels may be referred to as first sacrificial lines 112a, respectively, second ones of the sacrificial lines 112 at middle levels may be referred to as second sacrificial lines 112b, respectively, and third ones of the sacrificial lines 112 at upper levels may be referred to as third sacrificial lines 112c, respectively.

In example embodiments, the substrate 100 may include a semiconductor material, e.g., silicon, germanium, silicon-germanium, etc., or a III-V group compound, e.g., GaP, GaAs, GaSb, etc. In some embodiments, the substrate 100 may be a silicon-on-insulator (SOI) substrate or a germanium-on-insulator (GOI) substrate.

In example embodiments, the semiconductor lines 122 may include, e.g., silicon, and the sacrificial lines 112 may include a material having an etching selectivity with respect to the substrate 100 and the semiconductor lines 122, e.g., silicon-germanium. Each of the first and third sacrificial lines 112a and 112c may have a geranium concentration that is difference from that of the second sacrificial line 112b and thus may have an etch rate that is different from that of the second sacrificial line 112b.

FIG. 7 shows that each of the first to third sacrificial lines 112a, 112b and 112c is formed at two levels on the substrate 100, however, the present disclosure is not limited thereto. In an example embodiment, the second sacrificial line 112b may be formed at a single level, and a thickness of the second sacrificial line 112b may be greater than a thickness of each of the first and third sacrificial lines 112a and 112c.

In an example embodiment, the fin structure may extend in the first direction D1 on the substrate 100, and a plurality of fin structures may be spaced apart from each other in the second direction D2.

An isolation pattern 130 may be formed on the substrate 100 to cover the active pattern 105.

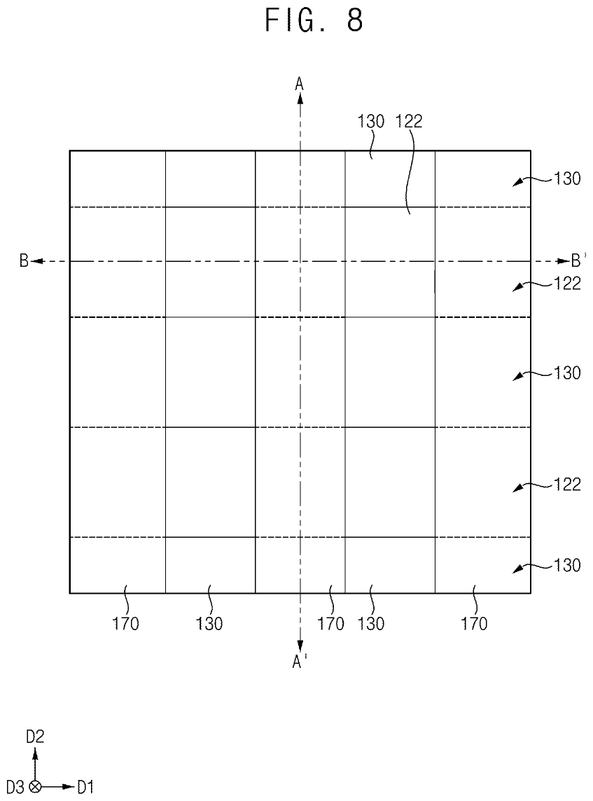

Referring to FIGS. 8, 9, and 10, a dummy gate insulation layer, a dummy gate electrode layer and a dummy gate mask layer may be sequentially formed on the substrate 100 to cover the fin structure and the isolation pattern 130, a second etching mask extending in the second direction D2 may be formed on the dummy gate mask layer, and the dummy gate mask layer may be etched using the second etching mask to form a dummy gate mask 160 on the substrate 100.

The dummy gate electrode layer and the dummy gate insulation layer may be etched using the dummy gate mask 160 as an etching mask to form a dummy gate electrode 150 and a dummy gate insulation pattern 140, respectively.

The dummy gate insulation pattern 140, the dummy gate electrode 150 and the dummy gate mask 160 may collectively form a dummy gate structure 170.

In example embodiments, the dummy gate structure 170 may extend in the second direction D2 on the fin structure and the isolation pattern 130 and may cover an upper surface and opposite sidewalls in the second direction D2 of the fin structure. In example embodiments, a plurality of dummy gate structures 170 may be spaced apart from each other in the first direction D1.

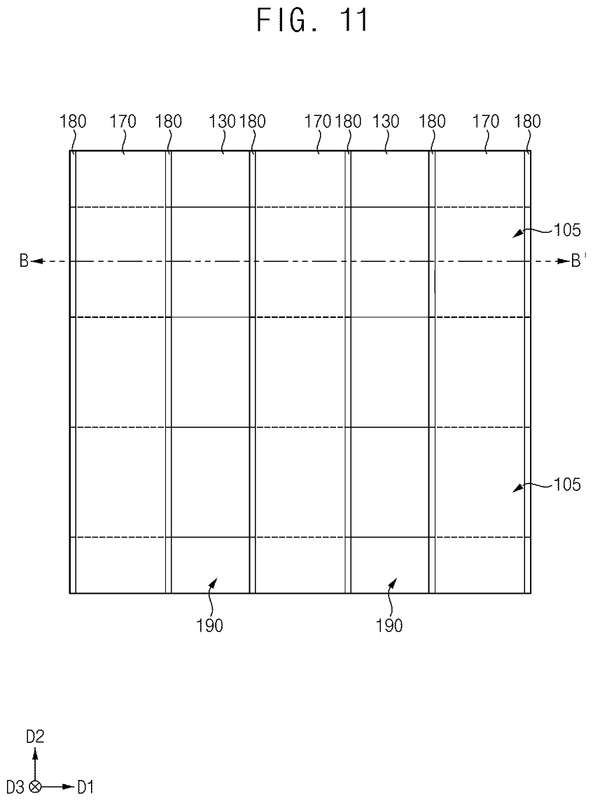

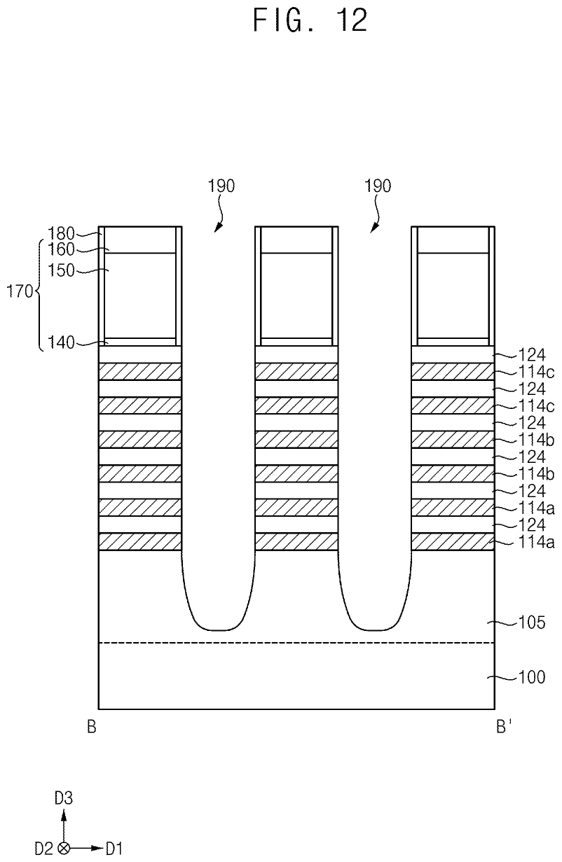

Referring to FIGS. 11 and 12, a gate spacer 180 may be formed on a sidewall of the dummy gate structure 170.

Particularly, a gate spacer layer may be formed on the fin structure, the isolation pattern 130 and the dummy gate structure 170 and may be anisotropically etched to form the gate spacer 180 covering each of opposite sidewalls in the first direction D1 of the dummy gate structure 170.

The fin structure and an upper portion of the active pattern 105 thereunder may be etched using the dummy gate structure 170 and the gate spacer 180 as an etching mask to form first openings 190.

Thus, the first to third sacrificial lines 112a, 112b and 112c and the semiconductor lines 122 may be transformed into first, second, and third sacrificial patterns 114a, 114b and 114c and semiconductor patterns 124, respectively, and the fin structure extending in the first direction D1 may be divided into a plurality of parts spaced apart from each other in the first direction D1.

Hereinafter, the dummy gate structure 170, the gate spacers 180 on opposite sidewalls of the dummy gate structure 170, and the fin structure may be referred to as a stack structure. In example embodiments, the stack structure may extend in the second direction D2, and a plurality of stack structures may be spaced apart from each other in the first direction D1.

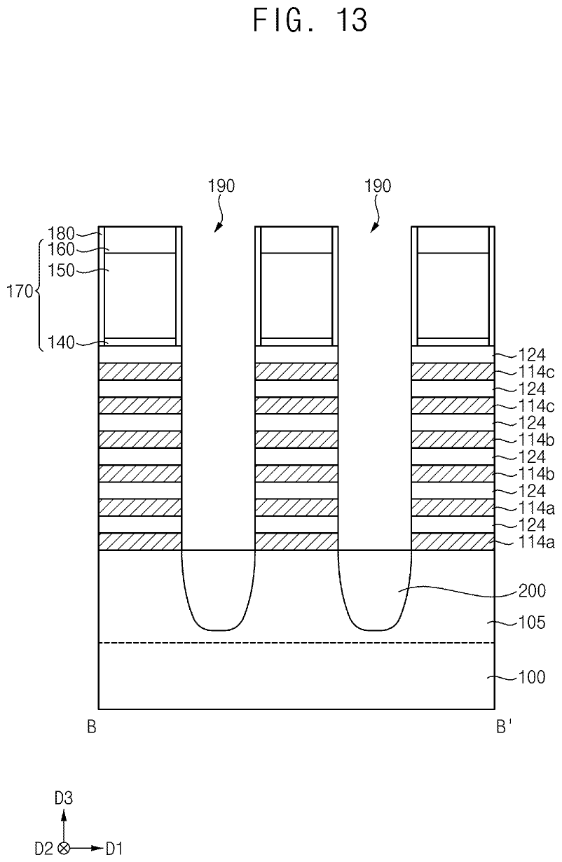

Referring to FIG. 13, a first SEG process may be performed using an upper surface and a sidewall of the active pattern 105 exposed by the first openings 190 as a seed to form an etch stop pattern 200 on the active pattern 105.

In example embodiments, the etch stop pattern 200 may include a material having an etching selectivity with respect to the active pattern 105, e.g., silicon-germanium.

FIG. 13 shows that an upper surface of the etch stop pattern 200 is substantially coplanar with the upper surface of the active pattern 105, however, the present disclosure is not limited thereto, and the upper surface of the etch stop pattern 200 may be higher or lower than the upper surface of the active pattern 105.

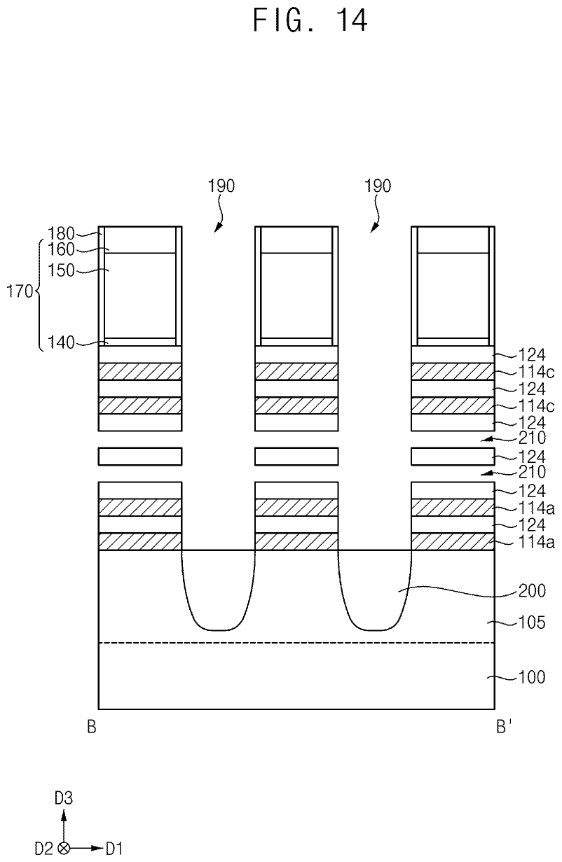

Referring to FIG. 14, an etching process may be performed to remove the second sacrificial patterns 114b exposed by the first openings 190, and thus a second opening 210 may be formed to expose lower surfaces and/or upper surfaces of the semiconductor patterns 124 adjacent to the second sacrificial patterns 114b in the third direction D3.

In example embodiments, the etching process may include a dry etching process and/or a wet etching process, and the semiconductor patterns 124 and the first and third sacrificial patterns 114a and 114c may not be etched during the etching process.

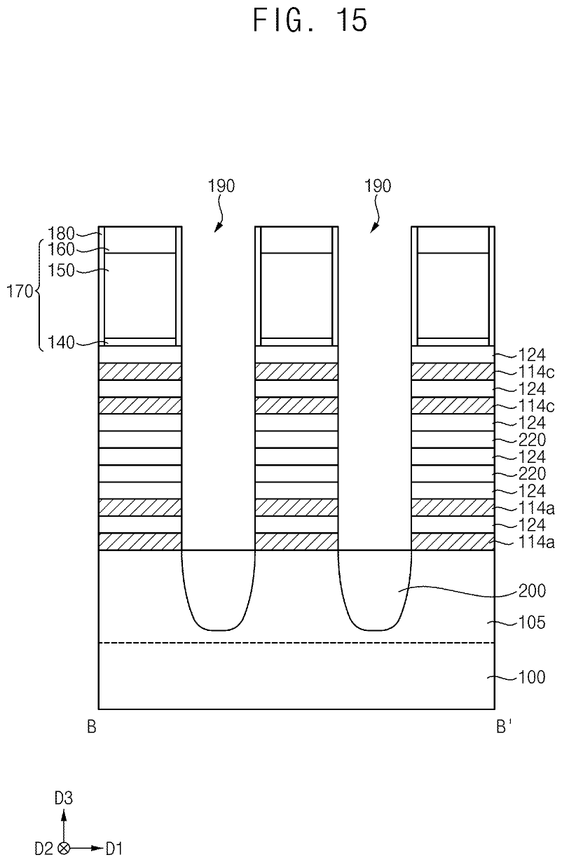

Referring to FIG. 15, a division pattern 220 may be formed in the second opening 210 between the semiconductor patterns 124 exposed by the second opening 210.

In example embodiments, the division pattern 220 may be formed on the exposed semiconductor patterns 124 by, e.g., a selective deposition process. Alternatively, the division pattern 220 may be formed by forming a division layer to fill the first and second openings 190 and 210 and performing an etching process using the dummy gate mask 160 and the gate spacer 180 as an etching mask, and the first openings 190 may be formed again.

In example embodiments, the division pattern 220 may include an insulating material, e.g., silicon nitride, silicon oxide, etc.

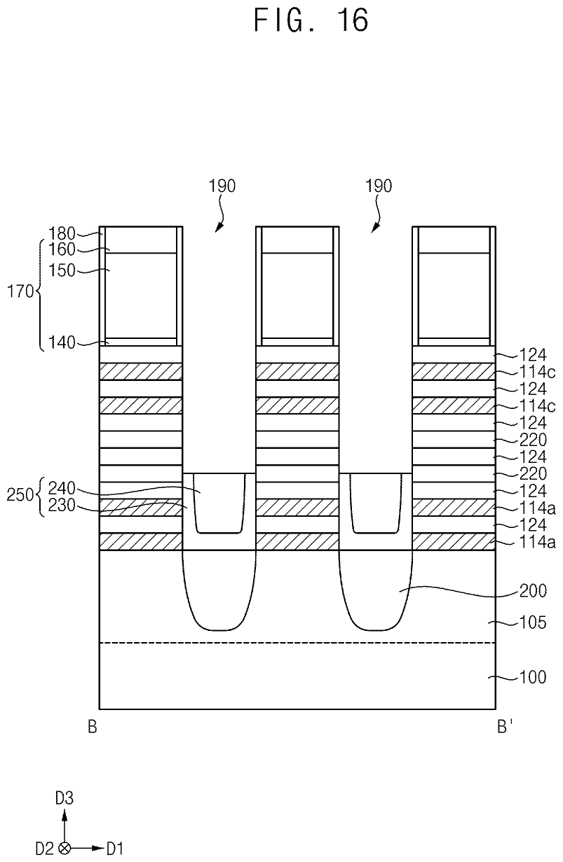

Referring to FIG. 16, a second SEG process may be performed using the upper surface of the etch stop pattern 200, sidewalls of the first sacrificial patterns 114a, and sidewalls of the semiconductor patterns 124 on the first sacrificial patterns 114a as a seed to form a first preliminary epitaxial pattern 230 between respective sidewalls of the stack structures neighboring in the first direction D1.

The first preliminary epitaxial pattern 230 may be formed on an inner wall of a lower portion of the first openings 190 and may cover the upper surface of the etch stop pattern 200, the sidewalls of the first sacrificial patterns 114a and the sidewalls of the semiconductor patterns 124 on the first sacrificial patterns 114a.

In example embodiments, the second SEG process may be performed using a silicon source gas, e.g., SiH₄, SiCl₂H₂, SiHCl₃, Si₂H₆, etc., and a germanium source gas, e.g., GeH₄. In some embodiments, the second SEG process may be performed also using p-type impurity source gas, e.g., B₂H₆. Thus, the first preliminary epitaxial pattern 230 may include silicon-germanium or silicon-germanium doped with p-type impurities.

A third SEG process may be performed using the first preliminary epitaxial pattern 230 as a seed to form a second preliminary epitaxial pattern 240 in the lower portion of the first openings 190.

In example embodiments, the third SEG process may be performed using a silicon source gas, e.g., SiH₄, SiCl₂H₂, SiHCl₃, Si₂H₆, etc., a germanium source gas, e.g., GeH₄, and p-type impurity source gas, e.g., B₂H₆, so that the second preliminary epitaxial pattern 240 may include silicon-germanium doped with p-type impurities.

FIG. 16 shows that upper surfaces of the first and second preliminary epitaxial patterns 230 and 240 are substantially coplanar with each other and higher than a lower surface of a lowermost one of the division patterns 220, however, the present disclosure is not limited thereto. In some embodiments, the upper surfaces of the first and second preliminary epitaxial patterns 230 and 240 may be substantially coplanar with the lower surface of the lowermost one of the division patterns 220.

The first and second preliminary epitaxial patterns 230 and 240 may form a preliminary source/drain layer 250. In example embodiments, a vertical cross-section of the preliminary source/drain layer 250 may have a shape of, e.g., pentagon, hexagon, etc.

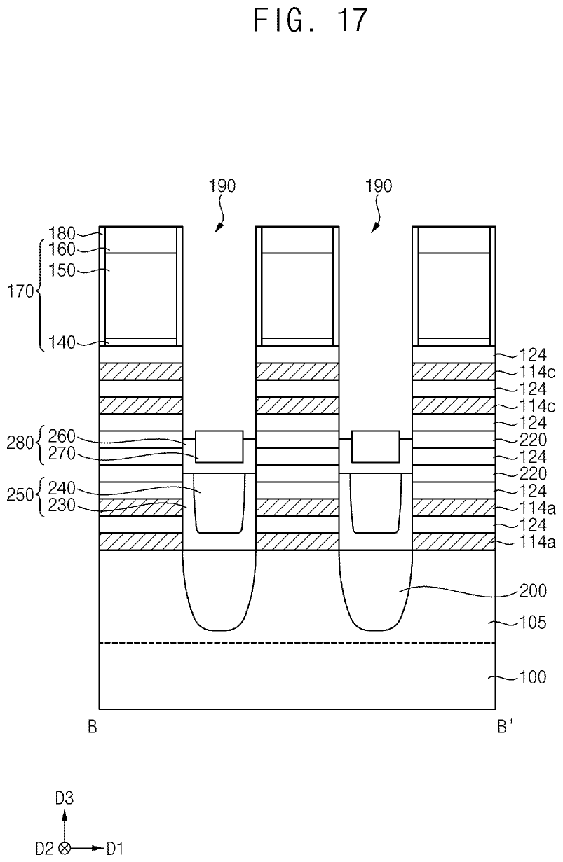

Referring to FIG. 17, a first insulation layer may be conformally formed on a sidewall of the first opening 190, an upper surface of the stack structure, an upper surface and a sidewall in the second direction D2 of the preliminary source/drain layer 250 and an upper surface of the isolation pattern 130, and a second insulation layer may be formed on the first insulation layer to fill the first opening 190.

The second insulation layer may be partially etched to form a second insulation pattern 270, and the first insulation layer may be partially etched to form a first insulation pattern 260.

In example embodiments, the first insulation pattern 260 may contact the upper surface and the sidewall in the second direction D2 of the preliminary source/drain layer 250 and the upper surface of the isolation pattern 130 and may also contact a portion of a sidewall of each of the division patterns 220 and the sidewall of the semiconductor patterns 124 between the division patterns 220. The second insulation pattern 270 may contact a surface of the first insulation pattern 260.

In example embodiments, the first insulation pattern 260 may include an insulating nitride, e.g., silicon nitride, and the second insulation pattern 270 may include an oxide, e.g., silicon oxide. The first and second insulation patterns 260 and 270 may form an insulation pattern structure 280.

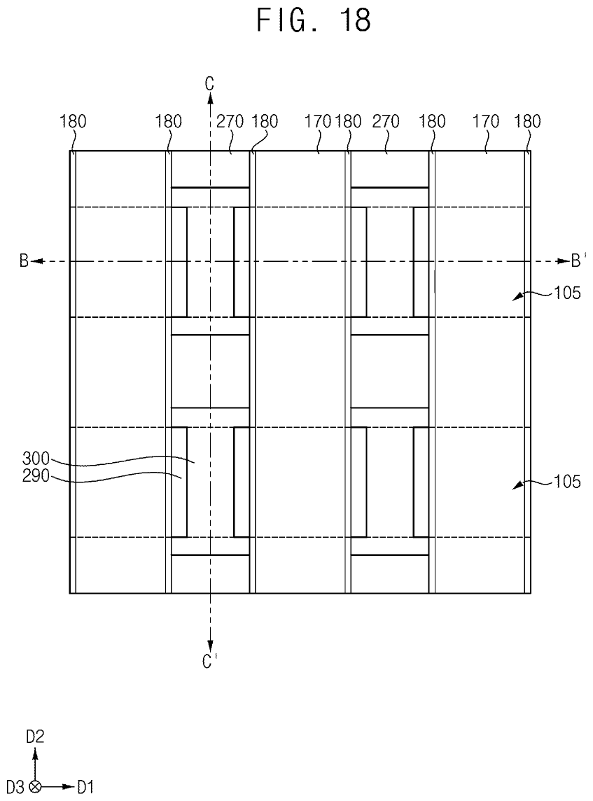

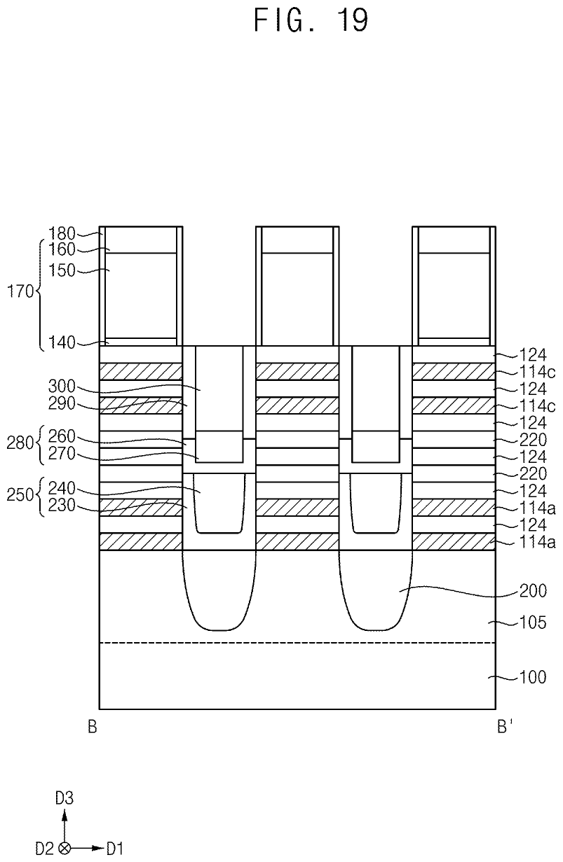

Referring to FIGS. 18, 19, adn 20, a fourth SEG process may be performed using sidewalls of the third sacrificial patterns 114c and the semiconductor patterns 124 adjacent thereto in the third direction D3 exposed by the first opening 190 as a seed to form a third preliminary epitaxial pattern 290 covering the inner wall of the first opening 190 on the first insulation pattern 260.

In example embodiments, the fourth SEG process may be performed using a silicon source gas, e.g., SiH₄, SiCl₂H₂, SiHCl₃, Si₂H₆, etc. In some embodiments, the fourth SEG process may be performed using also n-type impurity source gas including arsenic, phosphorus, etc. Thus, the third preliminary epitaxial pattern 290 may include silicon or silicon doped with n-type impurities. In an example embodiment, the third preliminary epitaxial pattern 290 may have a multi-layered structure of a first layer including silicon and a second layer including silicon doped with n-type impurities.

A fifth SEG process may be performed using a sidewall of the third preliminary epitaxial pattern 290 as a seed to form a sacrificial epitaxial pattern 300 in a remaining portion of the first opening 190.

In example embodiments, the fifth SEG process may be performed using a silicon source gas, e.g., SiH₄, SiCl₂H₂, SiHCl₃, Si₂H₆, etc., and a germanium source gas, e.g., GeH₄, so that the sacrificial epitaxial pattern 300 may include silicon-germanium.

The third preliminary epitaxial pattern 290 may be formed on each of opposite sidewalls of the stack structures neighboring in the first direction D1, and may have a shape of, e.g., a rectangle or a rectangle with rounded corners. The sacrificial epitaxial pattern 300 may be formed between the third preliminary epitaxial patterns 290 neighboring in the first direction D1 and between the stack structures neighboring in the first direction D1, and may have a shape of, e.g., an “H” in a plan view.

In example embodiments, a vertical cross-section in the second direction D2 of the sacrificial epitaxial pattern 300 may have a shape of, e.g., pentagon or hexagon.

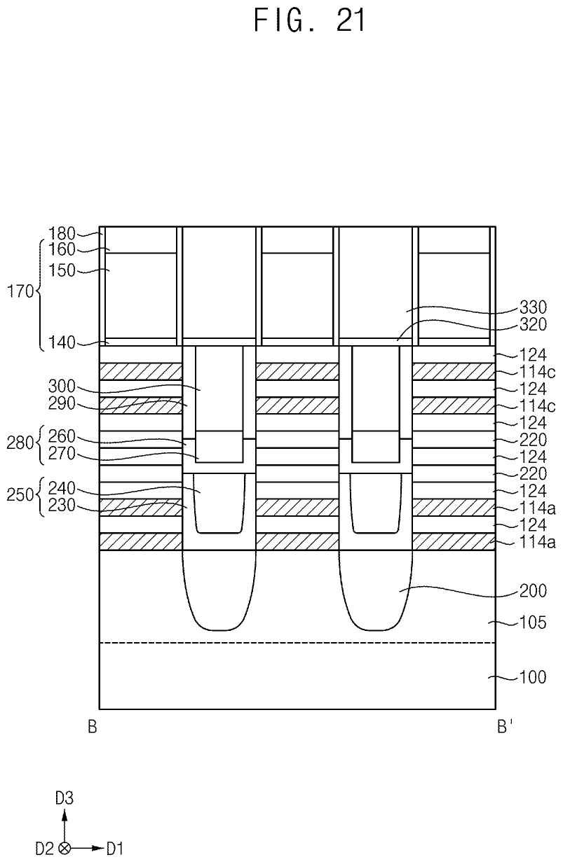

Referring to FIG. 21, a first capping pattern 320 may be formed on the third preliminary epitaxial pattern 290 and the sacrificial epitaxial pattern 300, a first insulating interlayer 330 may be formed on the first capping pattern 320, the insulation pattern structure 280 and the stack structure, and a planarization process may be performed on the first insulating interlayer 330 until the upper surface of the stack structure is exposed.

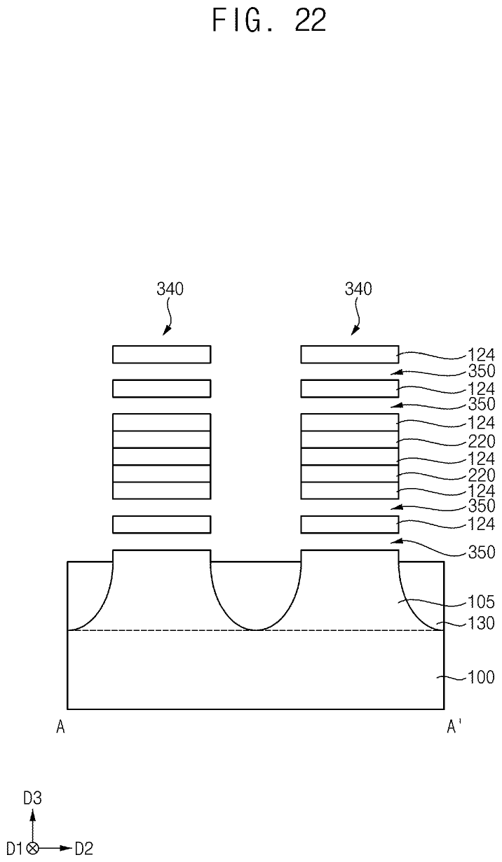

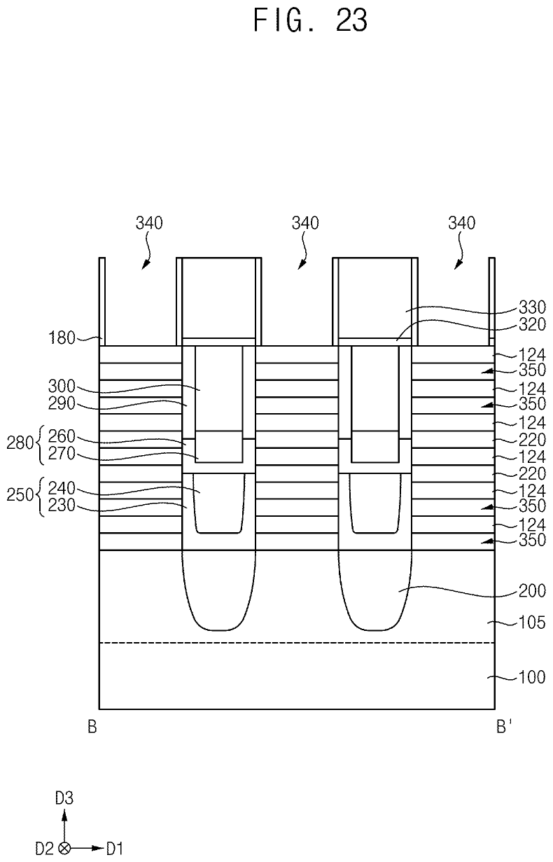

Referring to FIGS. 22 and 23, a planarization process may be performed until the dummy gate electrode 150 included in the stack structure is exposed to remove an upper portion of the first insulating interlayer 330 and the dummy gate mask 160 included in the dummy gate structure 170.

The dummy gate electrode 150, the dummy gate insulation pattern 140 and the first and third sacrificial patterns 114c may be removed by a wet etching process and/or a dry etching process.

Thus, a third opening 340 may be formed to expose an inner sidewall of the gate spacer 180 and an upper surface of an uppermost one of the semiconductor patterns 124. Additionally, a fourth opening 350 may be formed to expose surfaces of the semiconductor patterns 124, sidewalls of the first and third preliminary epitaxial patterns 230 and 290, and the upper surfaces of the active pattern 105 and the isolation pattern 130.

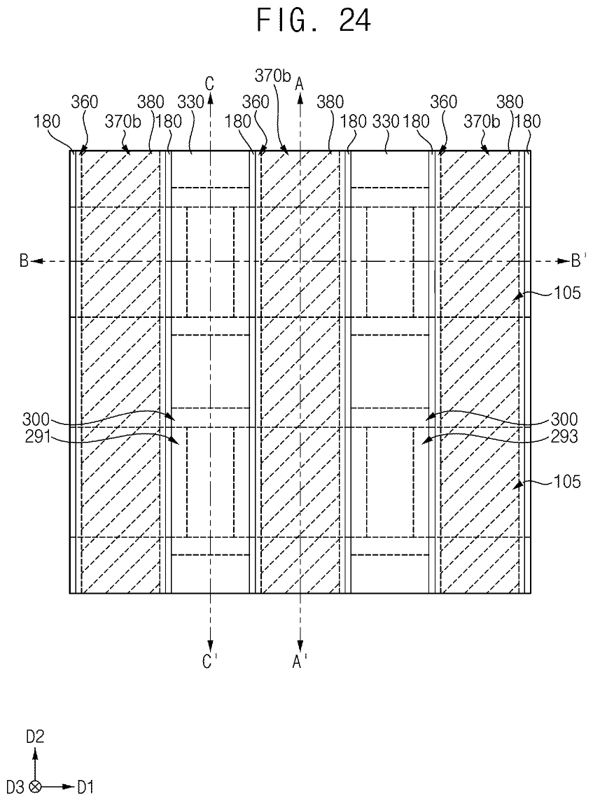

Referring to FIGS. 24, 25, 26, and 27, a gate insulation layer may be formed on the inner sidewall of the gate spacer 180, the surfaces of the semiconductor patterns 124 and the upper surfaces of the active pattern 105 and the isolation pattern 130 exposed by the third and fourth openings 340 and 350, and an upper surface of the first insulating interlayer 330.

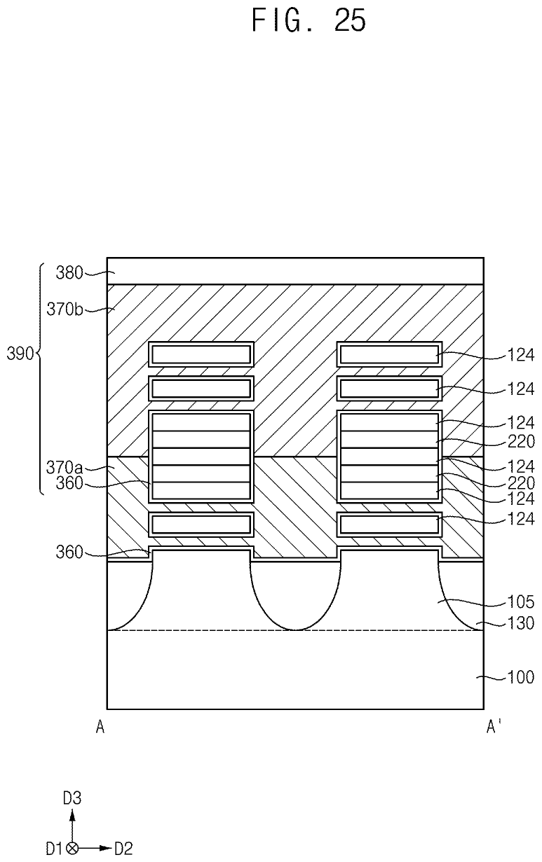

A first gate electrode layer may be formed on the gate insulation layer to fill a lower portion of the third and fourth openings 340 and 350, and a second gate electrode layer may be formed in an upper portion of the third and fourth openings 340 and 350. In example embodiments, an upper surface of the first gate electrode layer may be higher than a lower surface of a lowermost one of the division patterns 220, and a lower surface of the second gate electrode layer may be lower than an upper surface of an uppermost one of the division patterns 220. FIGS. 25 and 26 show that the first and second gate electrode layers include the same material so as to form a single layer structure, however, the present disclosure is not limited thereto. In some embodiments, the first and second gate electrode layers may have different materials from each other and have a multi-layered structure.

A planarization process may be performed on the first and second gate electrode layers and the gate insulation layer until the upper surface of the first insulating interlayer 330 is exposed, and thus first and second gate electrodes 370a and 370b and a first gate insulation pattern 360 may be formed in the third and fourth openings 340 and 350.

Upper portions of the first gate insulation pattern 360 and the second gate electrode 370b may be removed to form a second recess, and a second capping pattern 380 may be formed in the second recess. Thus, a first gate structure 390 including the first gate insulation pattern 360, the first and second gate electrodes 370a and 370b, and the second capping pattern 380 may be formed.

Hereinafter, the first preliminary epitaxial pattern 230, the second preliminary epitaxial pattern 240 and the third preliminary epitaxial pattern 290 on a first sidewall of the first gate structure 390 may be referred to as a first epitaxial pattern 231, a second epitaxial pattern 241 and a second source/drain layer 291, respectively, and the first preliminary epitaxial pattern 230, the second preliminary epitaxial pattern 240 and the third preliminary epitaxial pattern 290 on a second sidewall of the first gate structure 390 may be referred to as a third epitaxial pattern 233, a fourth epitaxial pattern 243 and a fourth source/drain layer 293, respectively. The first and second epitaxial patterns 231 and 241 may collectively form a first source/drain layer 251, and the third and fourth epitaxial patterns 233 and 243 may collectively form a third source/drain layer 253.

Referring to FIG. 28, the first insulating interlayer 330 and the first capping pattern 320 may be partially removed to form a fifth opening 391 exposing upper surfaces of the second source/drain layer 291 and the sacrificial epitaxial pattern 300 adjacent thereto, and a sixth opening 393 exposing upper surfaces of the fourth source/drain layer 293 and the sacrificial epitaxial pattern 300 adjacent thereto.

The sacrificial epitaxial patterns 300 exposed by the fifth and sixth openings 391 and 393 may be removed so that the fifth and sixth openings 391 and 393 may be enlarged downwardly. Thus, the fifth opening 391 may expose an upper surface of the second insulation pattern 270 and an inner sidewall of the second source/drain layer 291, and the sixth opening 393 may expose the upper surface of the second insulation pattern 270 and an inner sidewall of the fourth source/drain layer 293.

In example embodiments, the sacrificial epitaxial pattern 300 may be removed by an etching process, e.g., a dry etching process, and the sacrificial epitaxial pattern 300 may include a material different from those of the second and fourth source/drain layers 291 and 293. Thus, the sacrificial epitaxial pattern 300 may be selectively removed by the etching process even without an etching mask, and the second and fourth source/drain layers 291 and 293 may not be removed but remain.

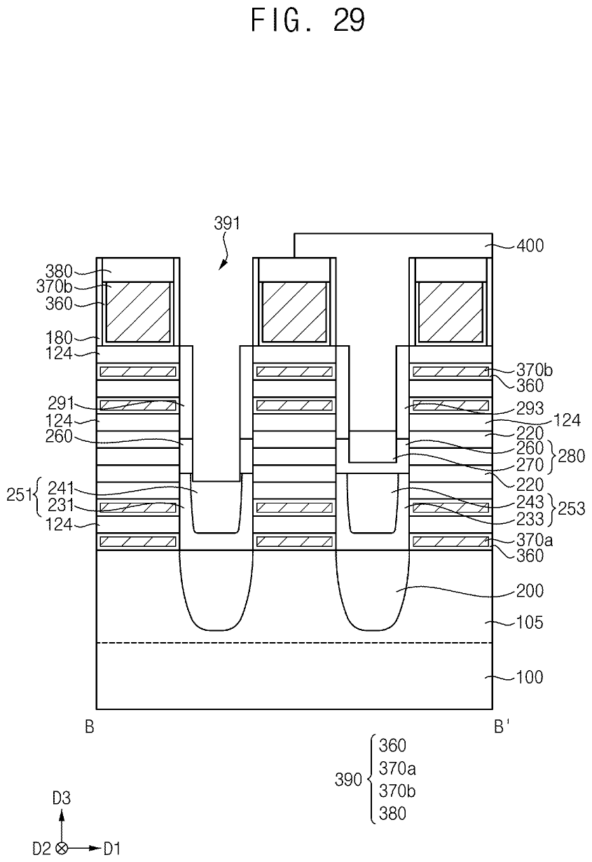

Referring to FIG. 29, a mask 400 may be formed on the fourth source/drain layer 293, the second insulation pattern 270 adjacent thereto, the first gate structure 390 and the gate spacer 180 to fill the sixth opening 393.

The second insulation pattern 270 exposed by the fifth opening 391, and a portion of the first insulation pattern 260 and an upper portion of the second epitaxial pattern 241 under the second insulation pattern 270 may be removed so that the fifth opening 391 may be enlarged downwardly, and thus a portion of an upper surface of the second epitaxial pattern 241 may be exposed.

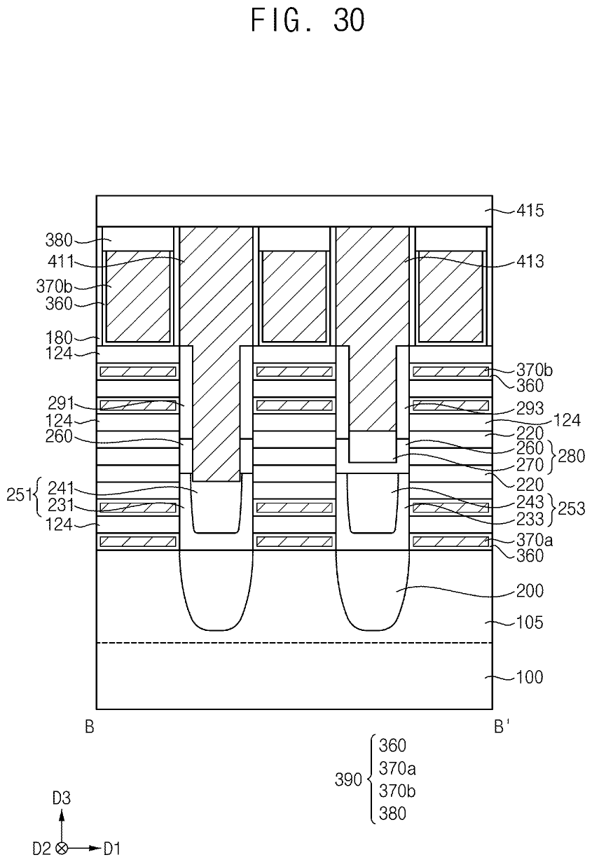

Referring to FIG. 30, the mask 400 may be removed, a first conductive layer may be formed on the first gate structure 390 and the gate spacer 180 to fill the fifth and sixth openings 391 and 393, and a planarization process may be performed until an upper surface of the second capping pattern 380 included in the first gate structure 390 is exposed to form first and second contact plugs 411 and 413 in the fifth and sixth openings 391 and 393, respectively.

In an example embodiment, a first ohmic contact pattern may be formed at an interface between the first contact plug 411 and the second epitaxial pattern 241 and at an interface pattern between the first contact plug 411 and the second source/drain layer 291, and a second ohmic contact pattern may be formed at an interface between the second contact plug 413 and the fourth source/drain layer 293.

The first and second ohmic contact patterns may be formed by forming a metal layer on the first source/drain layer 251, the insulation pattern structure 280, the second source/drain layer 291, and the fourth source/drain layer 293, performing an annealing process, and removing an unreacted portion of the metal layer. Each of the first and second ohmic contact patterns may include a metal silicide, e.g., titanium silicide, cobalt silicide, nickel silicide, etc.

An upper via (not shown) and an upper wiring (not shown) may be formed on the first gate structure 390, the first and second contact plugs 411 and 413 and the first insulating interlayer 330, and a second insulating interlayer 415 may be formed to cover the upper via and the upper wiring. In example embodiments, each of the upper via and the upper wiring may extend through the second insulating interlayer 415 and contact one of upper surfaces of the first and second contact plugs 411 and 413 and the second gate electrode 370b.

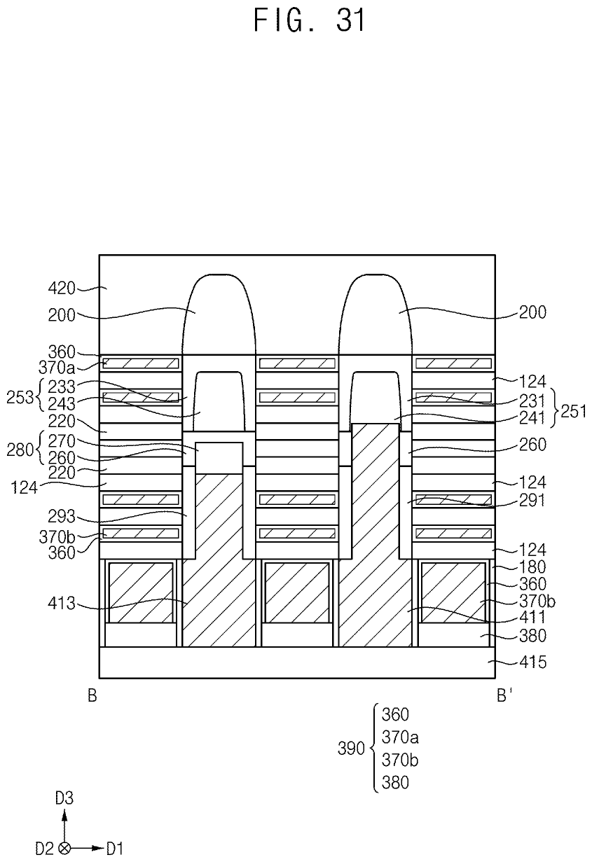

Referring to FIG. 31, the substrate 100 may be inverted, and accordingly, various structures on the substrate 100 may be turned upside down, and hereinafter, descriptions are made based on the inverted orientation.

For example, a grinding process may be performed on an upper portion of the substrate 100 to remove the upper portion of the substrate 100, and thus an upper surface of the active pattern 105 may be exposed.

A lower portion of the substrate 100 and an upper portion of the active pattern 105 may be removed until an upper surface of the etch stop pattern 200 is exposed. The lower portion of the substrate 100 and the upper portion of the active pattern 105 may be removed by, e.g., a grinding process, a chemical mechanical polishing (CMP) process, or an etching process, and the etch stop pattern 200 may serve as a polishing stop layer or an etch stop layer. The etch stop pattern 200 may include, e.g., silicon-germanium having a high concentration of germanium, and thus may not be removed during the polishing process or the etching process.

An additional etching process may be performed to remove the active pattern 105 between the etch stop patterns 200, and thus the upper surface and a sidewall of the etch stop pattern 200, an upper surface of the first gate structure 390 and an upper surface and a sidewall of the isolation pattern 130 may be exposed. A third insulating interlayer pattern 420 may be formed on the etch stop pattern 200, the first gate structure 390 and the isolation pattern 130.

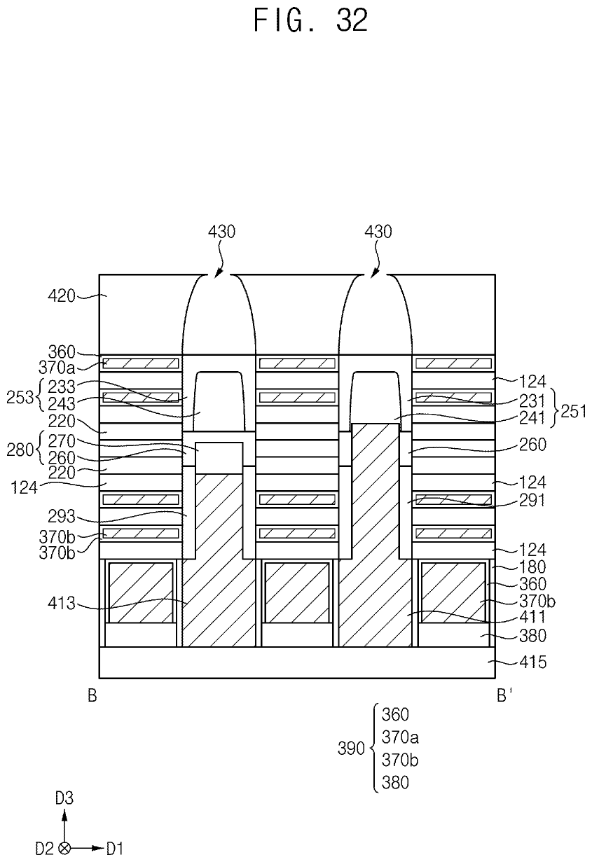

Referring to FIG. 32, a planarization process may be performed on the third insulating interlayer pattern 420 to expose the upper surface of the etch stop pattern 200, and the etch stop pattern 200 may be removed to form a seventh opening 430 exposing upper surfaces of the first and third source/drain layers 251 and 253 and a sidewall of the third insulating interlayer pattern 420.

Referring to FIGS. 1, 2, 3, 4, and 5 again, a second conductive layer may be formed on the first and third source/drain layers 251 and 253 and the third insulating interlayer pattern 420 to fill the seventh opening 430, and a planarization process may be performed on the second conductive layer until an upper surface of the third insulating interlayer pattern 420 is exposed to form a third contact plug 440.

A fourth insulating interlayer 450 including a lower wiring and a lower via may be formed on the third contact plug 440 and the third insulating interlayer pattern 420. In example embodiments, each of the lower via and the lower wiring may extend through the fourth insulating interlayer 450 to contact one of the third contact plugs 440. The lower wiring may serve as a power rail.

The structure may be inverted so as to complete the fabrication of the first semiconductor device 1.

As illustrated above, the first and third source/drain layers 251 and 253 and the insulation pattern structure 280 may be formed in lower portions of the first openings 190, which may be formed between neighboring ones of the stack structures in the first direction D1, the second and fourth source/drain layers 291 and 293 may be formed on the inner sidewalls of the upper portions of the first openings 190 by the fourth SEG process, and the sacrificial epitaxial patterns 300 may be formed in the upper portions of the first openings 190 by the fifth SEG process. The sacrificial epitaxial patterns 300 may be selectively removed to form the fifth and sixth openings 391 and 393, the insulation pattern structures 280 may be partially removed to enlarge the fifth opening 391 downwardly, the first contact plug 411 may be formed in the fifth opening 391 to contact the upper surface of the first source/drain layer 251 and the sidewall of the second source/drain layer 291, and the second contact plug 413 may be formed in the sixth opening 393 to contact the sidewall of the fourth source/drain layer 292. Thus, the first contact plug 411 may be formed to be aligned with the sidewall of the second source/drain layer 291, and the second contact plug 413 may be formed to be aligned with the sidewall of the fourth source/drain layer 293.

If the second source/drain layer 291 is formed in the upper portion of the first opening 190, the second source/drain layer 291 and the insulation pattern structure 280 are partially etched by an etching process using an etching mask to form the fifth opening 391, and the first contact plug 411 is formed in the fifth opening 391, the etching mask may collapse so that the etching process may be well performed, and the characteristics of the second source/drain layer 291 may be deteriorated by the etching process.

If the second source/drain layer 291 contacting the first contact plug 411 connected to the first and second source/drain layers 251 and 291 disposed in the third direction D3 is formed only on the inner sidewall of the upper portion of the first opening 190, and the fourth source/drain layer 293 contacting the second contact plug 413 connected only to the fourth source/drain layer 293 is formed to fill the upper portion of the first opening 190, the second and fourth source/drain layers 291 and 293 may not be formed by the same SEG process but may be formed by independent SEG processes.

However, in example embodiments, the fifth and sixth openings 391 and 393 for forming the first and second contact plugs 411 and 413 may be formed by the dry etching process without an etching mask, so that the sacrificial epitaxial pattern 300 having a high etching selectivity with respect to the second and fourth source/drain layers 291 and 293 may be selectively removed, and thus etching defects caused by collapse of the etching mask and characteristic degradation of the second and fourth source/drain layers 291 and 293 due to the etching process may be prevented.

Additionally, the second and fourth source/drain layers 291 and 293 may be formed by the same SEG process on the inner sidewall of the upper portion of the first opening 190, and thus the processes of manufacturing the first semiconductor device may be simplified.

The second and fourth source/drain layers 291 and 293 may be formed to have the same shape by the same SEG process so as to have the same electrical performance. The first and second contact plugs 411 and 413 may be formed in the fifth and sixth openings 391 and 393, which may be formed by removing the sacrificial epitaxial patterns 300 by the same process, and thus the first and second contact plugs 411 and 413 may have the same shape.

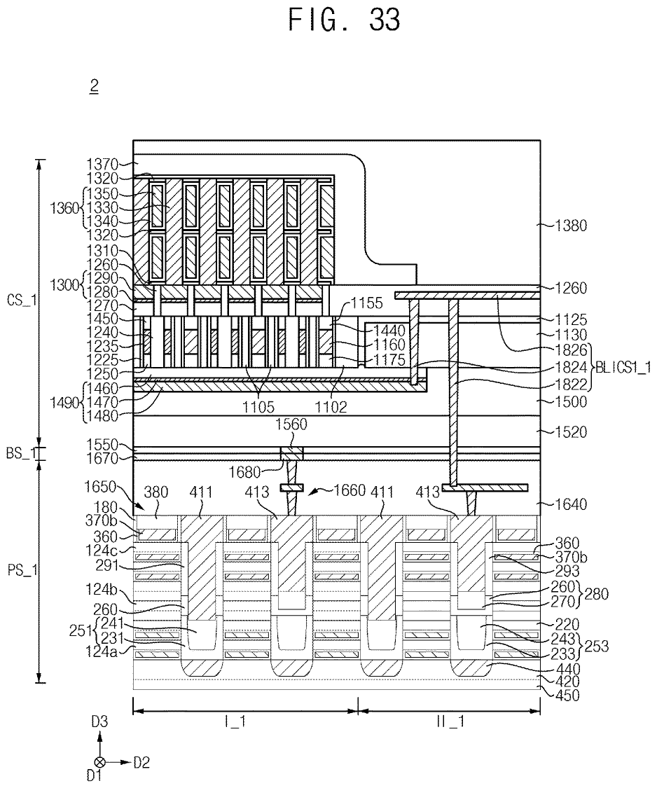

FIG. 33 is a cross-sectional view illustrating a second semiconductor device 2 in accordance with example embodiments.

The second semiconductor device 2 may be an application of the first semiconductor device into a DRAM device, and thus repeated explanations of the first semiconductor device are omitted herein.

Referring to FIG. 33, the second semiconductor device 2 may include a cell structure CS_1, a bonding structure BS_1, a peripheral circuit structure PS_1 and a bit line wiring structure BLICS1_1.

In example embodiments, the second semiconductor device 2 may have a cell over periphery (COP) structure. That is, the cell structure CS_1 may be disposed on the peripheral circuit structure PS_1. Alternatively, the second semiconductor device 2 may have a periphery over cell (POC) structure in which the peripheral circuit structure PS_1 is disposed on the cell structure CS_1.

The cell structure CS_1 may include a first region I_1 and a second region II_1 in a plan view. In example embodiments, the first region I-1 may be a cell array region, and the second region II_1 may be an extension region, and the first and second regions I_1 and II_1 may collectively form a cell region.

Hereinafter, portions of the peripheral circuit structure PS_1 and the bonding structure BS_1 overlapping the first region I_1 of the cell structure CS_1 in the third direction D3 may also be referred to as the first region I_1, and portions of the peripheral circuit structure PS_1 and the bonding structure BS_1 overlapping the second region II_1 of the cell structure CS_1 in the third direction D3 may also be referred to as the second region II_1.

The peripheral circuit structure PS_1 may include a peripheral circuit pattern 1650, a wiring structure 1660 and a fifth insulating interlayer 1640.

The peripheral circuit pattern 1650 may include a transistor included in the first semiconductor device.

The peripheral circuit pattern 1650 may include, e.g., a bit line sense amplifier (BLSA), a sub-word line driver (SWD), a column decoder, a column select line (CSL) driver, an input/output sense amplifier, a write driver, etc.

The wiring structure 1660 may be disposed on the fourth insulating interlayer 450 and may be electrically connected to the peripheral circuit pattern 1650. The wiring structure 1660 may include contact plugs, vias, wirings, pads, etc.

FIG. 33 shows that the vias included in the wiring structure 1660 contact the second contact plug 413, however, the present disclosure is not limited thereto, and the contact plugs, the vias, the wirings and the pads included in the wiring structure may have various layouts.

The fifth insulating interlayer 1640 may be disposed on the fourth insulating interlayer 450 and may cover the peripheral circuit pattern 1650 and the wiring structure 1660. The fifth insulating interlayer 1640 may include, e.g., silicon oxide, silicon nitride, a low-k dielectric material, etc.

The bonding structure PS_1 may include first and second bonding layers 1550 and 1670 and first and second bonding pads 1560 and 1680.

The second bonding layer 1670 and the first bonding layer 1550 may be sequentially stacked on the fifth insulating interlayer 1640 and may form a bonding layer structure. The second bonding pad 1680 and the first bonding pad 1560 may be disposed in the second bonding layer 1670 and the first bonding layer 1550, respectively, and may be bonded to each other. The first and second bonding pads 1560 and 1680 may include a metal, e.g., copper, and the first and second bonding layers 1550 and 1670 may include an insulating material, e.g., silicon carbonitride, silicon oxide, etc.

The cell structure CS_1 may include a bit line structure 1490, second and third gate structures, a first channel 1105, a fourth contact plug 1270, a landing pad structure 1300, a capacitor 1360 and a plate electrode 1370.

The cell structure CS_1 may further include a first etch stop pattern 1125, a third insulation pattern 1130, a fourth insulation pattern 1240, third to sixth capping patterns 1175, 1250, 1440 and 1450, sixth to ninth insulating interlayers 1500, 1520, 1260 and 1380, a second etch stop pattern 1310 and a support layer 1320.

The seventh insulating interlayer 1520 may be disposed on the first bonding layer 1550 and the first bonding pad 1560. The seventh insulating interlayer 1520 may include, e.g., silicon oxide, silicon nitride, a low-k dielectric material.

The bit line structure 1490 may extend in the second direction D2 in a first region I_1 and a portion of the second region II_1 adjacent thereto in the second direction D2, and a plurality of bit line structures 1490 may be spaced apart from each other in the first direction D1.

In example embodiments, the bit line structure 1490 may include third, fourth and fifth conductive patterns 1480, 1470 and 1460 sequentially stacked in the third direction D3. The third conductive pattern 1460 may include, e.g., doped polysilicon, the fourth conductive pattern 1470 may include a metal silicide, e.g., titanium silicide, tungsten silicide, etc., and the fifth conductive pattern 1480 may include a metal, e.g., tungsten, titanium, etc., or a metal nitride, e.g., titanium nitride.

The sixth insulating interlayer 1500 may be disposed on the seventh insulating interlayer 1520 and may cover a lower surface and a sidewall of the bit line structure 1490. The sixth insulating interlayer 1500 may include, e.g., silicon oxide, silicon nitride, a low-k dielectric material.

In example embodiments, a plurality of first channels 1105 may be spaced apart from each other in the second direction D2 on an upper surface of each of the bit line structures 1490 extending in the second direction D2, and thus the plurality of first channels 1105 may be spaced apart from each other in each of the first and second directions D1 and D2. Each of the first channels 1105 may extend in the third direction D3 to a given length.

The first channel 1105 may include a semiconductor material, e.g., silicon, germanium, silicon-germanium.

The second gate structure may be disposed in the first region I_1 and a portion of the second region II_1 adjacent thereto in the first direction D1 and may contact upper surfaces of the bit line structure 1490 and the sixth insulating interlayer 1500. The second gate structure may include a third gate electrode 1160 extending in the first direction D1 and a second gate insulation pattern 1155 extending in the first direction D1 on each of opposite sidewalls in the second direction D2 of the third gate electrode 1160. The second gate insulation pattern 1155 may contact a first sidewall in the second direction D2 of the first channel 1105.

In example embodiments, the third gate electrode 1160 may serve as a back-gate of the second semiconductor device 2.

The third gate electrode 1160 may include a conductive material, e.g., a metal, a metal nitride, a metal silicide, etc., and the second gate insulation pattern 1155 may include an oxide, e.g., silicon oxide.

A fifth capping pattern 1440 and a third capping pattern 1175 may be disposed on and beneath, respectively, the third gate electrode 1160, and a lower surface of the third capping pattern 1175 may contact an upper surface of the bit line structure 1490. The second gate insulation pattern 1155 may contact each of opposite sidewalls in the second direction D2 of each of the third and fifth capping patterns 1175 and 1440.

In example embodiments, the lower surface of the third capping pattern 1175 may be substantially coplanar with lower surfaces of the second gate insulation pattern 1155 and the first channel 1105, and an upper surface of the fifth capping pattern 1440 may be substantially coplanar with upper surfaces of the second gate insulation pattern 1155 and the first channel 1105.

Each of the third and fifth capping patterns 1175 and 1440 may include an insulating material, e.g., silicon nitride.

The third gate structure may be disposed in the first region I_1 and a portion of the second region II_1 adjacent thereto in the first direction D1 and may contact the upper surfaces of the bit line structure 1490 and the sixth insulating interlayer 1500. The third gate structure may include a fourth gate electrode 1235 extending in the first direction D1 and a third gate insulation pattern 1225 extending in the first direction D1 on a sidewall in the second direction D2 of the fourth gate electrode 1235. The third gate insulation pattern 1225 may contact a second sidewall in the second direction D2 of the first channel 1105 and opposite sidewalls in the first direction D1 and a sidewall of the second gate insulation pattern 1155.

In example embodiments, the fourth gate electrode 1235 may serve as a front-gate of the second semiconductor device 2, that is, a word line.

The fourth gate electrode 1235 may include a conductive material, e.g., a metal, a metal nitride, a metal silicide, etc., and the third gate insulation pattern 1225 may include an oxide, e.g., silicon oxide.

A sixth capping pattern 1450 and a fourth capping pattern 1250 may be disposed on and beneath, respectively, the fourth gate electrode 1235, and a lower surface of the fourth capping pattern 1250 may contact the upper surface of the bit line structure 1490. The third gate insulation pattern 1225 may contact a sidewall in the second direction D2 of each of the fourth and sixth capping patterns 1250 and 1450.

In example embodiments, the lower surface of the fourth capping pattern 1250 may be substantially coplanar with lower surfaces of the third gate insulation pattern 1225 and the first channel 1105, and an upper surface of the sixth capping pattern 1450 may be substantially coplanar with an upper surface of the third gate insulation pattern 1225 and the upper surface of the first channel 1105.

Each of the fourth and sixth capping patterns 1250 and 1450 may include an insulating material, e.g., silicon nitride.

The second gate structure and the third gate structure at each of opposite sides in the second direction D2 may form a first structure. In example embodiments, a plurality of first structures may be disposed in the second direction D2.

The fourth insulation pattern 1240 may be disposed in the first region I_1 and a portion of the second region II_1 adjacent thereto and may contact the upper surfaces of the bit line structure 1490 and the sixth insulating interlayer 1500. The fourth insulation pattern 1240 may extend in the first direction D1 between neighboring ones of the first structures in the second direction D2 and may contact a sidewall of each of the fourth gate electrode 1235 and the fourth and sixth capping patterns 1250 and 1450.

In example embodiments, an upper surface of the fourth insulation pattern 1240 may be substantially coplanar with the upper surface of the sixth capping pattern 1450.

The fourth insulation pattern 1240 may include an oxide, e.g., silicon oxide, or an insulating nitride, e.g., silicon nitride.

The dummy channel 1102 may be disposed in a portion of the first region I_1 adjacent to the second region II_1 in the second direction D2 and may contact the upper surfaces of the bit line structure 1490 and the sixth insulating interlayer 1500. The dummy channel 1102 may extend in the first direction D1 and may contact a sidewall in the second direction D2 of the second gate insulation pattern 1155.

In example embodiments, the dummy channel 1102 may include a material substantially the same as that of the first channel 1105, e.g., a semiconductor material such as silicon, germanium, silicon-germanium, etc.

The third insulation pattern 1130 may be disposed in the second region II_1 and may contact the upper surfaces of the bit line structure 1490 and the sixth insulating interlayer 1500.

The first etch stop pattern 1125 may include a first portion and a second portion. The first portion of the first etch stop pattern 1125 may contact an upper surface of the third insulation pattern 1130 and have a shape of a plane extending in the horizontal direction. The second portion of the first etch stop pattern 1125 may extend from the first portion in the third direction D3 and have a shape of a plane extending in the vertical direction. The second portion of the first etch stop pattern 1125 may contact a sidewall in the second direction D2 of the dummy channel 1102. Thus, a cross-section of the first etch stop pattern 1125 taken along a plane defined by the second and third directions D2 and D3 may have a vertically inverted “L” shape.

In example embodiments, an upper surface of the first portion of the first etch stop pattern 1125 may be substantially coplanar with the upper surfaces of the dummy channel 1102, the first channel 1105, the fifth and sixth capping patterns 1440 and 1450 and the second and third gate insulation patterns 1155 and 1225. In example embodiments, the second portion of the first etch stop pattern 1125 may contact the upper surfaces of the bit line structure 1490 and the sixth insulating interlayer 1500.

The first etch stop pattern 1125 may include an insulating nitride, e.g., silicon nitride.

The fourth contact plug 1270 may contact the upper surface of the first channel 1105, and the landing pad structure 1300 may contact an upper surface of the fourth contact plug 1270. Thus, a plurality of fourth contact plugs 1270 may be spaced apart from each other in each of the first and second directions D1 and D2 and may be arranged in a lattice pattern or a honeycomb pattern in a plan view. Additionally, a plurality of landing pad structures 1300 may be spaced apart from each other in each of the first and second directions D1 and D2 and may be arranged in a lattice pattern or a honeycomb pattern in a plan view.

The fourth contact plug 1270 may contact the upper surface of the channel 1105, upper surfaces of portions of the second and third gate insulation patterns 1155 and 1225 and the sixth capping pattern 1450 adjacent to the channel 1105 in the second direction D2, and upper surfaces of portions of the fourth insulation pattern 1240 and the fifth capping pattern 1440 adjacent to the channel 1105 in the second direction D2.

The landing pad structure 1300 may include first and second conductive patterns 1280 and 1290 sequentially stacked in the third direction D3.

The fourth contact plug 1270 may include, e.g., doped polysilicon, the first conductive pattern 1280 may include a metal silicide, e.g., titanium silicide, tungsten silicide, etc., and the second conductive pattern 1290 may include a metal, e.g., tungsten, titanium, etc., or a metal nitride, e.g., titanium nitride.

The eighth insulating interlayer 1260 may be disposed on the first etch stop pattern 1125, the dummy channel 1102, the first channel 1105, the second and third gate insulation patterns 1155 and 1225, the fifth and sixth capping patterns 1440 and 1450 and the fourth insulation pattern 1240 and may cover sidewalls of the fourth contact plug 1270 and the landing pad structure 1300. The eighth insulating interlayer 1260 may include, e.g., silicon oxide, silicon nitride, a low-k dielectric material, etc.

The second etch stop pattern 1310 may be disposed in the first region I_1 and may contact upper surfaces of the landing pad structure 1300 and the eighth insulating interlayer 1260. The second etch stop pattern 1310 may include an insulating nitride, e.g., silicon boronitride.

The capacitor 1360 may include a first capacitor electrode 1330, a dielectric layer 1340 and a second capacitor electrode 1350.

The first capacitor electrode 1330 may contact an upper surface of the landing pad structure 1300 and may extend in the third direction D3 to a given length. Thus, a plurality of first capacitor electrodes 1330 may be spaced apart from each other in each of the first and second directions D1 and D2. In example embodiments, the first capacitor electrodes 1330 may be arranged in a lattice pattern or a honeycomb pattern in a plan view.

Each of the first capacitor electrodes 1330 may extend through the second etch stop pattern 1310, and the support layer 1320 may be disposed on a sidewall of each of the first capacitor electrodes 1330. In example embodiments, a plurality of support layers 1320 may be spaced apart from each other in the third direction D3 on the sidewall of the first capacitor electrode 1330.

The dielectric layer 1340 may be disposed on a sidewall of the first capacitor electrode 1330, lower and upper surfaces and a sidewall of the support layer 1320, and an upper surface and a sidewall of the second etch stop pattern 1310, and the second capacitor electrode 1350 may be disposed between neighboring ones of the support layers 1320 in the third direction D3 and between a lowermost one of the support layers 1320 and the second etch stop pattern 1310. Lower and upper surfaces and a sidewall of the second capacitor electrode 1350 may be covered by the dielectric layer 1340.

The plate electrode 1370 may surround upper surfaces and sidewalls of the capacitor 1360, the support layer 1320 and the second etch stop pattern 1310.

Each of the first and second capacitor electrodes 1330 and 1350 may include a metal, a metal nitride, a metal silicide, etc., and the dielectric layer 1340 may include, e.g., a metal oxide. The support layer 1320 may include an insulating nitride, e.g., silicon nitride. The plate electrode 1370 may include, e.g., doped silicon-germanium, or a metal such as tungsten.

The ninth insulating interlayer 1380 may be disposed on the eighth insulating interlayer 1260 and the landing pad structure 1300 and may cover an upper surface and a sidewall of the plate electrode 1370. The ninth insulating interlayer 1380 may include, e.g., silicon oxide, silicon nitride, a low-k dielectric material, etc.

The bit line wiring structure BLICS1_1 may include first and second bit line contacts 1822 and 1824 and a bit line wiring 1826.

The first bit line contact 1822 may extend through a lower portion of the eighth insulating interlayer 1260, the first etch stop pattern 1125, the third insulation pattern 1130, the sixth and seventh insulating interlayers 1500 and 1520, the insulation layer structure, and an upper portion of the fifth insulating interlayer 1640 to contact the pad. The second bit line contact 1824 may extend through the lower portion of the eighth insulating interlayer 1260, the first etch stop pattern 1125 and the third insulation pattern 1130 to contact an upper portion of the bit line structure 1490. The bit line wiring 1826 may extend in the eighth insulating interlayer 1260 in the second direction D2 to contact upper surfaces of the first and second bit line contacts 1822 and 1824. The pad of the wiring structure 2760 may serve as a landing pad of the first bit line contact 1822.

In example embodiments, the upper surface of the first bit line contact 1822 may be disposed between the upper surface of the first channel 1105 and a lower surface of the capacitor 1360.

In the second semiconductor device 2, the third conductive pattern 1460 and the fourth contact plug 1270 included in the bit line structure 1490 may serve as source/drain layers, and a current may flow through the first channel 1105 in the third direction D3, that is, in the vertical direction. Thus, the second semiconductor device 2 may include a vertical channel transistor (VCT) having a vertical channel.

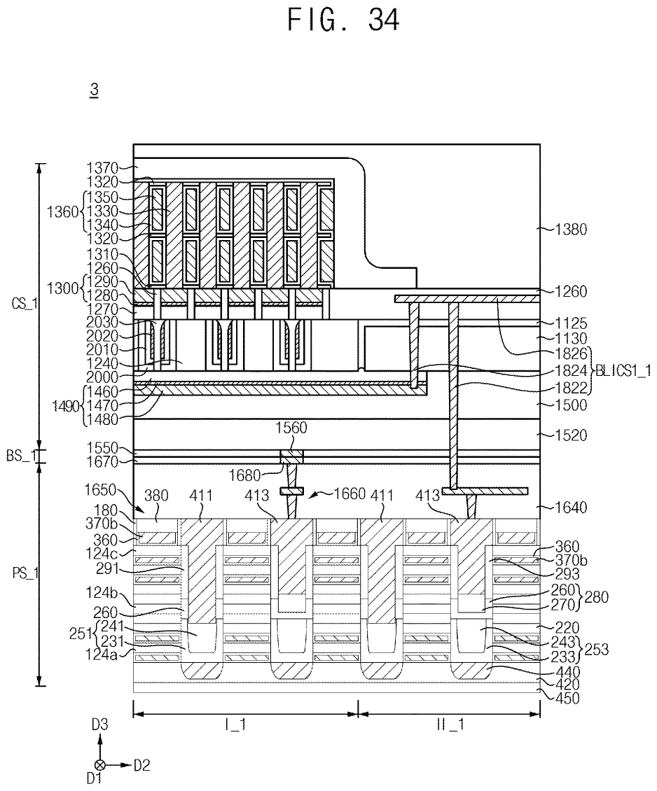

FIG. 34 is a cross-sectional view illustrating a third semiconductor device 3 in accordance with example embodiments.

The third semiconductor device 3 may be substantially the same as or similar to that of FIG. 33, except for including a fourth gate structure instead of the second and third gate structures, further including a ninth insulation pattern 2030 and a second channel 2000, not including the third to sixth capping patterns 1175, 1250, 1440 and 1450, and the shape of the fourth insulation pattern 1240, and thus repeated are omitted herein.

Referring to FIG. 34, the fourth insulation pattern 1240 may be disposed in the first region I_1 and a portion of the second region II_1 adjacent thereto in the first direction D1, and may contact upper surfaces of the bit line structure 1490 and the sixth insulating interlayer 1500. In example embodiments, the fourth insulation pattern 1240 may extend in the first direction D1, and a plurality of fourth insulation patterns 1240 may be spaced apart from each other in the second direction D2.

The ninth insulation pattern 2030 may extend in the first direction D1 between neighboring ones of the fourth insulation patterns 1240 in the second direction D2, and the fifth gate electrode 2020, the fourth gate insulation pattern 2010 and the second channel 2000 may be sequentially stacked in the second direction D2 between the fourth insulation pattern 1240 and the ninth insulation pattern 2030. In example embodiments, the ninth insulation pattern 2030 may extend in the first direction D1, and a plurality of ninth insulation patterns 2030 may be spaced apart from each other in the second direction D2. The fourth insulation pattern 1240 and the ninth insulation pattern 2030 may be alternately and repeatedly disposed in the second direction D2.

The second channel 2000 may contact the upper surface of the bit line wiring structure BLICS1_1 and may also contact opposite sidewalls of the fourth insulation pattern 1240 and the ninth insulation pattern 2030 neighboring in the second direction D2.

In example embodiments, a plurality of second channels 2000 may be spaced apart from each other in the first direction D1 by the fourth insulation pattern 1240 and the ninth insulation pattern 2030 on the bit line wiring structure BLICS1_1.

In example embodiments, the second channel 2000 may include a horizontal portion and a vertical portion. A lower portion of the horizontal portion of the second channel 2000 may contact the upper surface of the bit line wiring structure BLICS1_1, an inner sidewall in the first direction D1 of the horizontal portion of the second channel 2000 may contact the sidewall of the ninth insulation pattern 2030, and an outer sidewall in the first direction D1 of the horizontal portion of the second channel 2000 may contact the sidewall of the fourth insulation pattern 1240. The vertical portion of the second channel 2000 may be disposed on and contact the horizontal portion thereof, an inner sidewall in the first direction D1 of the vertical portion of the second channel 2000 may contact the fourth gate insulation pattern 2010, and an outer sidewall in the first direction D1 of the vertical portion of the second channel 2000 may contact the sidewall of the fourth insulation pattern 1240. In example embodiments, a vertical cross-section in the first direction D1 of the second channel 2000 may have an “L” shape.

In example embodiments, the second channel 2000 may include an oxide semiconductor material. For example, the second channel 2000 may include at least one of, e.g.,, zinc tin oxide (ZTO), indium zinc oxide (IZO), zinc oxide, indium gallium zinc oxide (IGZO), indium gallium silicon oxide (IGSO), indium oxide, tin oxide, titanium oxide, zinc oxide nitride, magnesium zincoxide, indium zinc oxide, indium gallium zinc oxide, zirconium indium zinc oxide, hafnium indium zinc oxide, tin indium zinc oxide, aluminum tin indium zinc oxide, silicon indiumzinc oxide, zinc tin oxide, aluminum zinc tin oxide, gallium zinc tin oxide, zirconium zinc tin oxide, and indium gallium silicon oxide.

The fourth gate insulation pattern 2010 may include a horizontal portion and a vertical portion. The horizontal portion of the fourth gate insulation pattern 2010 may contact an upper surface of the second channel 2000, and the vertical portion of the fourth gate insulation pattern 2010 may contact an inner sidewall of the vertical portion of the second channel 2000. A vertical cross-section in the second direction D2 of the fourth gate insulation pattern 2010 may have an “L” shape.

Particularly, an inner sidewall in the second direction D2 of the horizontal portion of the fourth gate insulation pattern 2010 may contact the ninth insulation pattern 2030, and an outer sidewall in the second direction D2 of the horizontal portion of the fourth gate insulation pattern 2010 may contact the inner sidewall of the vertical portion of the second channel 2000 and the sidewall of the fourth insulation pattern 1240. An outer sidewall in the first direction D1 of the vertical portion of the fourth gate insulation pattern 2010 may contact the inner sidewall of the vertical portion of the second channel 2000 and the sidewall of the fourth insulation pattern 1240.

The fourth gate insulation pattern 2010 may include a first portion contacting the inner sidewall of the vertical portion of the second channel 2000, and a second portion contacting the sidewall of the fourth insulation pattern 1240.

In example embodiments, the fourth gate insulation pattern 2010 may extend in the first direction D1. However, the fourth gate insulation pattern 2010 may extend in the first direction D1 while being bent in the second direction D2, rather than extending in a straight line along the first direction D1. The first portion and the second portion of the fourth gate insulation pattern 2010 may not be aligned with each other by the second channel 2000 in the first direction D1, and the first and second portions of the fourth gate insulation pattern 2010 may be alternately and repeatedly disposed in the first direction D1, so that the fourth gate insulation pattern 2010 may extend in the first direction D1 while being bent in the second direction D2.

In example embodiments, an uppermost surface of the fourth gate insulation pattern 2010 may be substantially coplanar with an uppermost surface of the second channel 2000. The fourth gate insulation pattern 2010 may include an oxide, e.g., silicon oxide.

The fifth gate electrode 2020 may be disposed on the fourth gate insulation pattern 2010. An inner sidewall in the second direction D2 of the fifth gate electrode 2020 may contact the ninth insulation pattern 2030, an outer sidewall in the second direction D2 of the fifth gate electrode 2020 may contact an inner sidewall of the vertical portion of the fourth gate insulation pattern 2010, and a lower surface of the fifth gate electrode 2020 may contact an upper surface of the horizontal portion of the fourth gate insulation pattern 2010.

In example embodiments, the fifth gate electrode 2020 may include a first portion on the first portion of the fourth gate insulation pattern 2010, and a second portion on the second portion of the fourth gate insulation pattern 2010. The fifth gate electrode 2020 may extend in the first direction D1 while being bent in the second direction D2, rather than extending in a straight line along the first direction D1. The first portion and the second portion of the fifth gate electrode 2020 may not be aligned with each other by the fourth gate insulation pattern 2010 in the first direction D1, and the first and second portions of the fifth gate electrode 2020 may be alternately and repeatedly disposed in the first direction D1, so that the fifth gate electrode 2020 may extend in the first direction D1 while being bent in the second direction D2.

In example embodiments, an uppermost surface of the fifth gate electrode 2020 may be lower than the uppermost surface of the fourth gate insulation pattern 2010. The fifth gate electrode 2020 may include a conductive material, e.g., a metal, a metal nitride, a metal silicide, etc.

The ninth insulation pattern 2030 may include a first portion and a second portion. The first portion of the ninth insulation pattern 2030 may contact the inner sidewall of the horizontal portion of the second channel 2000, the inner sidewall of the first portion of the fourth gate insulation pattern 2010, and the inner sidewall of the first portion of the fifth gate electrode 2020. The second portion of the ninth insulation pattern 2030 may contact the inner sidewall of the second portion of the fourth gate insulation pattern 2010 and the inner sidewall of the second portion of the fifth gate electrode 2020. In example embodiments, a width in the second direction D2 of the first portion of the ninth insulation pattern 2030 may be smaller than a width in the second direction D2 of the second portion of the ninth insulation pattern 2030, and thus a width in the second direction D2 of the ninth insulation pattern 2030 may periodically vary in the first direction D1.

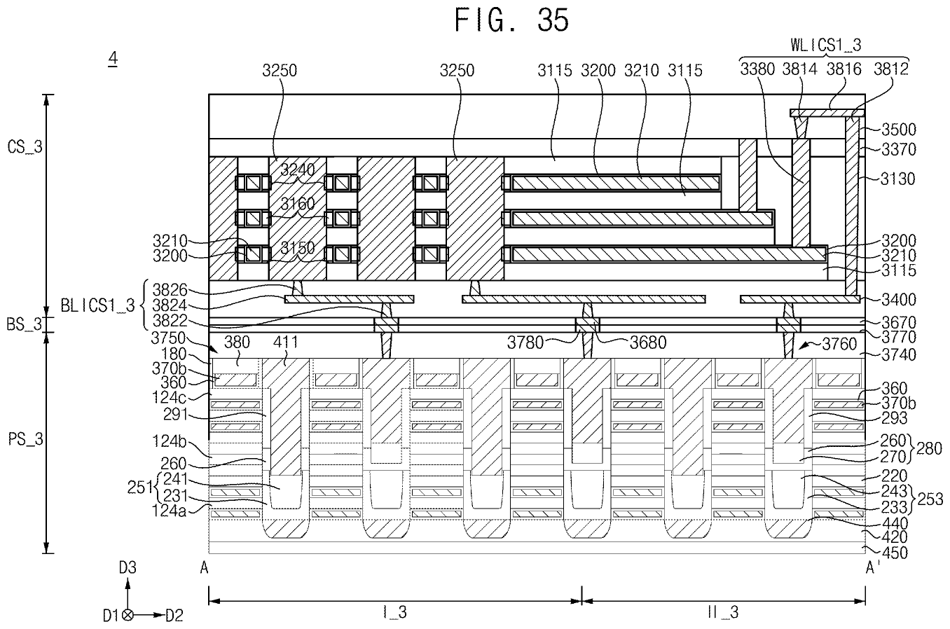

FIG. 35 is a cross-sectional view illustrating a fourth semiconductor device 4 in accordance with example embodiments.

The fourth semiconductor device 4 may be an application of the first semiconductor device into a DRAM device, and thus repeated explanations of the first semiconductor device are omitted herein.

Referring to FIG. 35, the fourth semiconductor device 4 may include a peripheral circuit structure PS_3, a bonding structure BS_3, a cell structure CS_3, a word line wiring structure WLICS1_3, and a bit line wiring structure BLICS1_3.

In example embodiments, the fourth semiconductor device 4 may have a COP structure. Thus, the cell structure CS_3 may be disposed on the peripheral circuit structure PS_3. Alternatively, the fourth semiconductor device 4 may have a POC structure, and the peripheral circuit structure PS_3 may be disposed on the cell structure CS_3.

The cell structure CS_3 may include a first region I_3 and a second region II_3 in a plan view. In example embodiments, the first region I_3 may be a cell array region, and the second region II_3 may be an extension region. The first and second regions I_3 and II_3 may collectively form a cell region.

Hereinafter, portions of the peripheral circuit structure PS_3 and the bonding structure BS_3 overlapping the first region I_3 of the cell structure CS_3 in the third direction D3 may also be referred to as the first region I_3, and portions of the peripheral circuit structure PS_3 and the bonding structure BS_3 overlapping the second region II_3 of the cell structure CS_3 in the third direction D3 may also be referred to as the second region II_3.

The peripheral circuit structure PS_3 may include a peripheral circuit pattern 3750, a wiring structure 3760 and a fifth insulating interlayer 3740.

The peripheral circuit pattern 3750, the wiring structure 3760 and the fifth insulating interlayer 3740 of the peripheral circuit structure PS_3 may be substantially the same as the peripheral circuit pattern 1650, the wiring structure 1660 and the fifth insulating interlayer 1640, respectively, of the peripheral circuit structure PS_1 included in the second semiconductor device 2.

The bonding structure PS_3 may include first and second bonding layers 3670 and 3770 and first and second bonding pads 3680 and 3780. The first and second bonding pads 3680 and 3780 may collectively form a bonding pad structure, and the first and second bonding layers 3670 and 3770 may collectively form a bonding layer structure.

The first and second bonding layers 3670 and 3770 and the first and second bonding pads 3680 and 3780 of the bonding structure PS_3 included in the fourth semiconductor device 4 may be substantially the same as the first and second bonding layers 1550 and 1670 and the first and second bonding pads 1560 and 1680, respectively, of the bonding structure PS_1 included in the second semiconductor device 2.

The cell structure CS_3 may include a third gate electrode 3210, a second gate insulation layer 3200, a bit line 3250, a first channel 3160, a third ohmic contact patterns 3240, and a capacitor structure (not shown).

The cell structure CS_3 may further include a first insulation pattern 3115, a third insulation layer 3150, and sixth to tenth insulating interlayers 3130, 3370, 3400, 3370 and 3500.

The third gate electrode 3210 may extend in the second direction D2 in the first and second regions I_3 and II_3, and a plurality of third gate electrodes 3210 may be spaced apart from each other in the third direction D3 to form a first gate electrode structure. The third insulation pattern 3115 may be disposed between neighboring ones of the third gate electrodes 3210 in the third direction D3, and the third insulation pattern 3115 may also be disposed under a lowermost one of the third gate electrodes 3210 and on an uppermost one of the third gate electrodes 3210. Each of the third gate electrodes 3210 may serve as a word line in the fourth semiconductor device 4, and thus the first gate electrode structure may also be referred to as a word line structure.

In example embodiments, extension lengths in the second direction D2 of the third gate electrodes 3210 may decrease in a stepwise manner from a lowermost level toward an uppermost level, and thus the first gate electrode structure may have a staircase shape. A portion of each of the third gate electrodes 3210 that is not overlapped by overlying ones of the third gate electrodes 3210 in the third direction D3, that is, each of end portions in the second direction D2 may be referred to as a pad. In example embodiments, the pads may be arranged in the second direction D2 in the second region II_3.

The third gate electrode 3210 may include, e.g., a metal, a metal nitride, a metal silicide, doped polysilicon, etc.

In example embodiments, a plurality of first gate electrode structures may be spaced apart from each other in the first direction D1.

The third insulation pattern 3115 may include an oxide, e.g., silicon oxide.

The second gate insulation layer 3200 may cover lower and upper surfaces and a sidewall facing the first channel 3160 of the third gate electrode 3210. The second gate insulation layer 3200 may include an oxide, e.g., silicon oxide.

The bit line 3250 may be disposed in the first region I_3, and may have a shape of, e.g., a pillar shape extending in the third direction D3, and may extend through the first gate electrode structure and the third insulation patterns 3115. In example embodiments, the bit line 3250 may extend through the first gate electrode structure extending in the second direction D2, and a plurality of bit lines 3250 may be spaced apart from each other in the second direction D2. Thus, the bit lines 3250 may be spaced apart from each other in each of the first and second directions D1 and D2. The bit line 3250 may include, e.g., a metal, a metal nitride, a metal silicide, doped polysilicon, etc.

The first channel 3160 may be disposed at a level where the third gate electrode 3210 is disposed and may be disposed on a sidewall of the bit line 3250. The third ohmic contact pattern 3240 may be disposed between the first channel 3160 and the bit line 3250. The second gate insulation layer 3200 may be disposed between the first channel 3160 and the third gate electrode 3210.

Lower and upper surfaces of the first channel 3160 may be covered by the third insulation layer 3150, and the third insulation layer 3150 may contact a sidewall of a portion of the third insulation pattern 3115 between neighboring ones of the first channels 3160 in the third direction D3. The third insulation layer 3150 may include an oxide, e.g., silicon oxide, and in some cases, may be merged to the third insulation pattern 3115.

In example embodiments, the first channel 3160 may have a shape of, e.g., a circular ring, an elliptical ring, a polygonal ring, etc. In example embodiments, a plurality of first channels 3160 may be spaced apart from each other in the third direction D3. Additionally, a plurality of first channels 3160 may be spaced apart from each other in each of the first and second directions D1 and D2.

The first channel 3160 may include an oxide semiconductor material. For example, the first channel 3160 may include at least one of, at least one of, e.g., zinc tin oxide (ZTO), indium zinc oxide (IZO), zinc oxide, indium gallium zinc oxide (IGZO), indium gallium silicon oxide (IGSO), indium oxide, tin oxide, titanium oxide, zinc oxide nitride, magnesium zincoxide, indium zinc oxide, indium gallium zinc oxide, zirconium indium zinc oxide, hafnium indium zinc oxide, tin indium zinc oxide, aluminum tin indium zinc oxide, silicon indiumzinc oxide, zinc tin oxide, aluminum zinc tin oxide, gallium zinc tin oxide, zirconium zinc tin oxide, and indium gallium silicon oxide.

The third ohmic contact pattern 3240 may include a metal silicide, e.g., cobalt silicide, nickel silicide, titanium silicide, etc.

In an example embodiment, the third ohmic contact pattern 3240 may not be disposed between the first channel 3160 and a sidewall of the bit line 3250, and in this case, an impurity region including n-type impurities or p-type impurities may be formed in a lateral portion of the first channel 3160 facing the sidewall of the bit line 3250.

The sixth and seventh insulating interlayers 3130 and 3370 may be sequentially stacked in the third direction D3 on the ninth insulating interlayer 3400, the sixth insulating interlayer 3130 may cover sidewalls of the first gate electrode structure and the third insulation patterns 3115. The seventh insulating interlayer 3370 may be disposed on the sixth insulating interlayer 3130, the first gate electrode structure, the bit line 3250, the capacitor structure and the third insulation layer 3150. Each of the sixth and seventh insulating interlayers 3130 and 3370 may include an oxide, e.g., silicon oxide.

The word line wiring structure WLICS_3 may include a first word line contact 3380, a second word line contact 3812, a third word line contact 3814 and a word line wiring 3816.

The first word line contact 3380 may extend through the sixth and seventh insulating interlayers 3130 and 3370 and the second gate insulation layer 3200 to contact an upper surface of the pad of the third gate electrode in the second region II_3. The second word line contact 3812 may extend through a lower portion of the eighth insulating interlayer 3500, the seventh insulating interlayer 3370, the sixth insulating interlayer 3130, the ninth insulating interlayer 3400 and the tenth insulating interlayer 3740 and may contact the pad of the wiring structure 3760. The third word line contact 3814 may extend through the lower portion of the eighth insulating interlayer 3500 and may contact an upper surface of the first word line contact 3380. The word line wiring 3816 may extend in the second direction D2 in the eighth insulating interlayer 3500 and may contact upper surfaces of the second and third word line contacts 3812 and 3814. The pad of the wiring structure 3760 may serve as a landing pad of the second word line contact 3812.

The bit line wiring structure BLICS_3 may include a first bit line contact 3822, a bit line wiring 3824 and a second bit line contact 3826.

The first bit line contact 3822 may extend through a lower portion of the ninth insulating interlayer 3400 and may contact an upper surface of the bonding pad structure. The bit line wiring 3824 may extend in the second direction D2 in the ninth insulating interlayer 3400 and may contact an upper surface of the second bit line contact 3822. The second bit line contact 3826 may extend through an upper portion of the ninth insulating interlayer 3400, and may contact a lower surface of the bit line 3250 and an upper surface of the bit line wiring 3824.

According to aspects of the disclosure, a method of manufacturing a semiconductor device includes: forming a dummy gate structure on a substrate; forming a first source/drain layer on a portion of the substrate adjacent to the dummy gate structure; forming an insulation pattern structure on the first source/drain layer; forming a second source/drain layer and a sacrificial epitaxial pattern on the insulation pattern structure; replacing the dummy gate structure with a first gate structure: partially removing the sacrificial pattern and the insulation pattern structure to form a first opening; and forming a first contact plug in the first opening.

According to aspects of the disclosure, a cross-section in a horizontal direction of a portion of the first contact plug at the same level as the second source/drain layer has a shape of an “H.”

According to aspects of the disclosure, the method further includes, prior to forming the first source/drain layer: removing an upper portion of the substrate adjacent to the dummy gate structure to form a recess; and forming an etch stop pattern in the recess.

According to aspects of the disclosure, the method further includes removing the etch stop pattern to form a second opening; and forming a second contact plug in the second opening.

According to aspects of the disclosure, forming the second contact plug includes: replacing the substrate with an insulating interlayer; removing the etch stop pattern to form a third opening exposing the first source/drain layer; and forming a second contact plug in the third opening.

According to aspects of the disclosure, the method further includes, prior to forming the dummy gate structure on the substrate, forming a fin structure including at least one sacrificial line and at least one semiconductor line alternately stacked on the substrate in a vertical direction perpendicular to an upper surface of the substrate, wherein the dummy gate structure is formed on the fin structure, and wherein each of the first and second source/drain layers contacts the fin structure.

According to aspects of the disclosure, the at least one sacrificial line includes a plurality of sacrificial lines, the plurality of sacrificial lines include first sacrificial lines at lower levels, second sacrificial lines at middle levels, and third sacrificial lines at upper levels, the method further comprises, prior to forming the first source/drain layer: removing each of the second sacrificial lines to form a second opening; and forming a division pattern in the second opening.

According to aspects of the disclosure, the second source/drain layer is formed by a selective epitaxial growth (SEG) process using a sidewall of the at least one semiconductor line as a seed, and wherein the method further comprises forming a sacrificial epitaxial pattern by a second SEG process using a sidewall of the second source/drain layer as a seed.

According to aspects of the disclosure, each of the first to third sacrificial lines includes silicon-germanium, and wherein a germanium concentration of each of the first and third sacrificial lines is difference from a germanium concentration of each of the second sacrificial lines.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present disclosure. Accordingly, all such modifications are intended to be included within the scope of the present disclosure as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A semiconductor device, comprising:
a first transistor including:
a first gate structure extending in a first direction;
first channels each extending through the first gate structure in a second direction crossing the first direction, the first channels being spaced apart from each other in a third direction perpendicular to the first and second directions; and
a first source/drain layer at a first side in the second direction of the first gate structure;
a second transistor on the first transistor, the second transistor including:
a second gate structure extending in the first direction;
second channels each extending through the second gate structure in the second direction, the second channels being spaced apart from each other in the third direction; and
a second source/drain layer at a first side in the second direction of the second gate structure; and
a first contact plug extending through the second source/drain layer and contacting an upper surface of the first source/drain layer,
wherein a first width in the second direction of a central portion in the first direction of the first contact plug is smaller than a second width in the second direction of each of opposite end portions in the first direction of the first contact plug.

2. The semiconductor device as claimed in claim 1, wherein a cross-section in a horizontal direction of a portion of the first contact plug extending through the second source/drain layer has a shape of an “H.”

3. The semiconductor device as claimed in claim 1, further comprising at least one division pattern including an insulating material and being disposed between an uppermost one of the first channels and a lowermost one of the second channels,
wherein the at least one division pattern at least partially overlaps each of the first and second channels in the third direction.

4. The semiconductor device as claimed in claim 3, wherein the at least one division pattern includes a plurality of division patterns disposed in the third direction.

5. The semiconductor device as claimed in claim 4, further comprising a dummy channel between neighboring ones of the plurality of division patterns, the dummy channel including silicon.

6. The semiconductor device as claimed in claim 1, wherein the second source/drain layer has a third width in the second direction, and
wherein a sum of the first width and the third width is equal to the second width.

7. The semiconductor device as claimed in claim 1, further comprising an insulation pattern structure between the first source/drain layer and the second source/drain layer,
wherein the first contact plug extends through the insulation pattern structure, and contacts an upper surface of the first source/drain layer.

8. The semiconductor device as claimed in claim 7, wherein:
the first transistor further includes a third source/drain layer at a second side in the first direction of the first gate structure,
the second transistor further includes a fourth source/drain layer at a second side in the first direction of the second gate structure,
the insulation pattern structure is disposed between the third source/drain layer and the fourth source/drain layer, and
the semiconductor device further includes a second contact plug extending through the fourth source/drain layer and contacting an upper surface of the insulation pattern structure.

9. The semiconductor device as claimed in claim 1, further comprising a third contact plug contacting a lower portion of the first source/drain layer.

10. The semiconductor device as claimed in claim 1, wherein a width in the first direction of the first contact plug gradually increases and then decreases from a top toward a bottom of the first contact plug.

11. The semiconductor device as claimed in claim 1, wherein the first source/drain layer includes a semiconductor material doped with p-type impurities, and the second source/drain layer includes a semiconductor material doped with n-type impurities,
12. The semiconductor device as claimed in claim 1, wherein the first and second gate structures include first and second gate electrodes, respectively, and
wherein an upper surface of the first gate electrode contacts a lower surface of the second gate electrode.

13. A semiconductor device, comprising:
a first gate structure;
first channels each extending through the first gate structure in a first direction, the first channels being spaced apart from each other in a second direction perpendicular to the first direction;
first and second source/drain layers at opposite sides, respectively, in the first direction of the first gate structure;
an insulation pattern structure on each of the first and second source/drain layers;
a second gate structure on the first gate structure;
second channels each extending through the second gate structure in the first direction, the second channels being spaced apart from each other in the second direction;
third and fourth source/drain layers at opposite sides, respectively, in the first direction of the second gate structure;
a first contact plug extending through the third source/drain layer and contacting an upper surface of the first source/drain layer; and
a second contact plug extending through the fourth source/drain layer and contacting an upper surface of the insulation pattern structure,
wherein the third source/drain layer and the fourth source/drain layer have the same shape.

14. The semiconductor device as claimed in claim 13, wherein the insulation pattern structure includes first and second insulation patterns sequentially stacked, and
wherein the second contact plug contacts an upper surface of the second insulation pattern.

15. The semiconductor device as claimed in claim 14, wherein the first insulation pattern includes an insulating nitride, and the second insulation pattern includes an oxide.

16. The semiconductor device as claimed in claim 13, wherein:
the first contact plug includes:
a lower portion contacting an upper surface of the first source/drain layer and a sidewall of the third source/drain layer; and
an upper portion disposed on the lower portion and contacting an upper surface of the third source/drain layer,
wherein a first width in the first direction of a central portion in a third direction crossing the first direction of the lower portion of the first contact plug is smaller than a second width in the first direction of each of opposite end portions in the third direction of the lower portion of the first contact plug.

17. The semiconductor device as claimed in claim 16, wherein a third width in the first direction of the upper portion of the first contact plug is equal to the second width.

18. A semiconductor device, comprising:
a first transistor including:
a first gate structure extending in a first direction;
first channels each extending through the first gate structure in a second direction crossing the first direction, the first channels being spaced apart from each other in a third direction perpendicular to the first and second directions; and
first and second source/drain layers at opposite sides, respectively, in the second direction of the first gate structure;
an insulation pattern structure on each of the first and second source/drain layers;
a second transistor on the first transistor, the second transistor including:
a second gate structure extending in the first direction;
second channels each extending through the second gate structure in the second direction, the second channels being spaced apart from each other in the third direction; and
third and fourth source/drain layers at opposite sides, respectively, in the second direction of the second gate structure on the insulation pattern structure;
a first contact plug extending through the third source/drain layer and contacting an upper surface of the first source/drain layer; and
a second contact plug extending through the fourth source/drain layer and contacting an upper surface of the insulation pattern structure.

19. The semiconductor device as claimed in claim 18, wherein a first width in the second direction of a central portion in the first direction of the first contact plug is smaller than a second with in the second direction of each of opposite end portions in the first direction of the first contact plug.

20. The semiconductor device as claimed in claim 18, wherein the third and fourth source/drain layers have the same shape.
